(19) United States
(12) Patent Application Publication
(10) Pub. No.: US 2023/0012724 A1
(43) Pub. Date: Jan. 19, 2023

(54) FILTER DEVICE

(71) Applicant: Murata Manufacturing Co., Ltd., Nagaokakyo-shi (JP)

(72) Inventors: Takayuki OKUDE, Nagaokakyo-shi (JP); Hiroyuki FURUSATO, Nagaokakyo-shi (JP); Seima KONDO, Nagaokakyo-shi (JP); Kota OKUBO, Nagaokakyo-shi (JP); Tomoya SATO, Nagaokakyo-shi (JP)

(21) Appl. No.: 17/859,409

(22) Filed: Jul. 7, 2022

(30) Foreign Application Priority Data
Jul. 8, 2021 (JP) 2021-113448

(51) Int. Cl. H03H 9/64; H03H 9/02; H03H 9/25; H03H 9/145

(52) U.S. Cl. CPC H03H 9/6483; H03H 9/02834; H03H 9/25; H03H 9/145

(57) ABSTRACT

A filter device includes a first series line, one or more first parallel lines extending from the first series line, two or more first series IDT electrodes on the first series line, and one or more first parallel IDT electrodes on the one or more first parallel lines. At least one of the two or more first series IDT electrodes is a first-type electrode. A dielectric layer is between the first-type electrode and a substrate. At least one of the two or more first series IDT electrodes except the first-type electrode and the one or more first parallel IDT electrodes is a second-type electrode directly contacting the substrate. A first series IDT electrode of the two or more first series IDT electrodes that has a largest pitch of electrode fingers is the first-type electrode.

### CROSS REFERENCE TO RELATED APPLICATIONS

This application claims the benefit of priority to Japanese Patent Application No. 2021-113448 filed on Jul. 8, 2021. The entire contents of this application are hereby incorporated herein by reference.

### BACKGROUND OF THE INVENTION

### 1. Field of the Invention

The present invention relates to a filter device.

### 2. Description of the Related Art

There is a band pass filter including a plurality of surface acoustic wave elements each including a piezoelectric substrate and an electrode portion formed on the piezoelectric substrate as a thin film (for example, see Japanese Patent No. 4036856).

### SUMMARY OF THE INVENTION

In the band pass filter described in Japanese Patent No. 4036856, in the surface acoustic wave element provided between an input terminal and an output terminal, an insulating material layer is provided between the comb-like electrode portion and the piezoelectric substrate. In the surface acoustic wave element provided between a ground potential and a signal line connecting the input terminal and the output terminal to each other, the comb-like electrode portion is directly formed on the piezoelectric substrate. With such a configuration, the band pass filter using the surface acoustic wave elements whose anti-resonant frequency and resonant frequency can be easily brought closer together is realized.

However, the technology described in Japanese Patent No. 4036856 only achieves limited band widening and has a difficulty in ensuring the steepness near the pass band and the stop band.

Preferred embodiments of the present invention provide filter devices each achieving a wide pass band or stop band and ensuring steepness near the pass band and the stop band.

A filter device according to an aspect of a preferred embodiment of the present invention includes a first series line that connects a first terminal and a second terminal to each other, one or more first parallel lines extending from the first series line, two or more first series IDT electrodes on the first series line, one or more first parallel IDT electrodes on the one or more first parallel lines, a substrate that is piezoelectric, and a dielectric layer on a portion of the substrate. At least one of the two or more first series IDT electrodes is a first-type electrode. The dielectric layer is between the first-type electrode and the substrate. At least one of the two or more first series IDT electrodes except the first-type electrode or at least one of the one or more first parallel IDT electrodes or any combination thereof is a second-type electrode directly contacting the substrate. The two or more first series IDT electrodes and the one or more first parallel IDT electrodes each include electrode fingers positioned at a pitch based on a resonant frequency. A first series IDT electrode of the two or more first series IDT electrodes that has the electrode fingers at the pitch that is largest is the first-type electrode.

According to preferred embodiments of the present invention, it is possible to provide filter devices each with a wide pass band or stop band and ensuring steepness near the pass band and the stop band.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a diagram illustrating the circuit configuration of a filter device 11.

FIG. 2 is a schematic view illustrating the overview of a first-type electrode 151.

FIG. 3 is a sectional view taken along the cutting line illustrated in FIG. 2.

FIG. 4 is a schematic view illustrating the cross section of the first-type electrode 151.

FIG. 5 is a schematic view illustrating the overview of a second-type electrode 152.

FIG. 6 is a sectional view taken along the cutting line VI-VI illustrated in FIG. 5.

FIG. 7 is a diagram illustrating frequency-dependent changes in impedance between the terminals of a first-type resonator and impedance between the terminals of a second-type resonator.

FIG. 8 is a diagram illustrating exemplary frequency characteristics of each series resonator.

FIG. 9 is a diagram illustrating exemplary frequency characteristics of a series resonator 132A and a first reference series resonator.

FIG. 10 is a diagram illustrating exemplary frequency characteristics of the filter device 11 and a first reference filter device.

FIG. 11 is a diagram illustrating the circuit configuration of a filter device 12.

FIG. 12 is a diagram illustrating exemplary frequency characteristics of each parallel resonator.

FIG. 13 is a diagram illustrating exemplary frequency characteristics of a parallel resonator 242A and a first reference parallel resonator.

FIG. 14 is a diagram illustrating exemplary frequency characteristics of the filter device 12 and a second reference filter device.

FIG. 15 is a diagram illustrating the circuit configuration of a filter device 13.

FIG. 16 is a schematic view illustrating the overview of series IDT electrodes 32 and 32S.

FIG. 17 is a diagram illustrating exemplary frequency characteristics of a series resonator 332 and a second reference series resonator.

FIG. 18 is a diagram illustrating the circuit configuration of a filter device 14.

FIG. 19 is a diagram illustrating the circuit configuration of a filter device 15.

FIG. 20 is a schematic view illustrating the overview of series IDT electrodes 32 and 32P.

FIG. 21 is a diagram illustrating exemplary frequency-dependent changes in insertion loss of a series resonator 532 and a third reference series resonator.

FIG. 22 is a diagram illustrating the circuit configuration of a filter device 16.

FIG. 23 is a diagram illustrating the circuit configuration of a filter device 17.

FIG. 24 is a diagram illustrating the circuit configuration of a filter device 18.

FIG. 25 is a diagram illustrating exemplary frequency characteristics of a filter 812.

FIG. 26 is a diagram illustrating exemplary frequency characteristics of a filter 813.

### DETAILED DESCRIPTION OF THE PREFERRED EMBODIMENTS

Now, preferred embodiments of the present invention are described in detail with reference to the drawings. Note that the same elements are denoted by the same reference characters to omit redundant description as much as possible.

### First Preferred Embodiment

A filter device according to a first preferred embodiment is described.

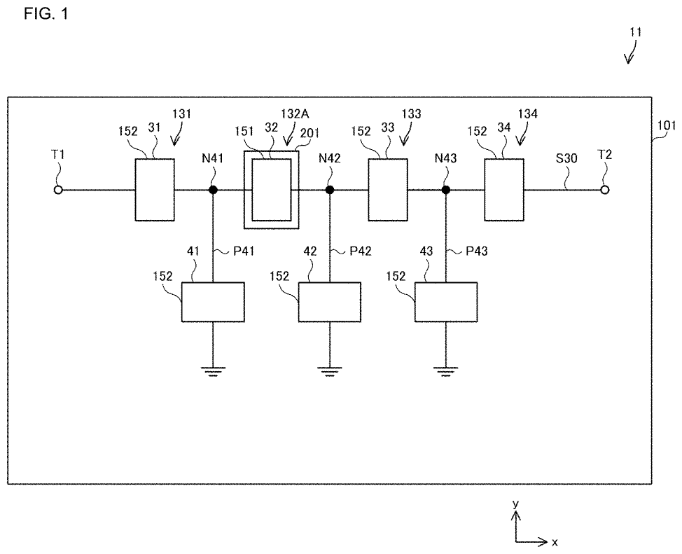

FIG. 1 is a diagram illustrating the circuit configuration of a filter device 11. Note that, in some drawings, an x axis, a y axis, and a z axis are illustrated. The x axis, the y axis, and the z axis form a right-handed three-dimensional Cartesian coordinate system. In the following, the arrow direction in the z axis is referred to as “+z-axis side” and the opposite direction of the arrow is referred to as “−z-axis side” in some cases. The same holds true for the other axes. Note that the +z-axis side and the −z-axis side are sometimes referred to as “above” and “bottom”, respectively.

As illustrated in FIG. 1, the filter device 11 according to the first preferred embodiment includes a series line S30 (first series line), three parallel lines P41 to P43 (first parallel lines), four series IDT electrodes 31 to 34 (first series IDT electrodes), three parallel IDT electrodes 41 to 43 (first parallel IDT electrodes), a substrate 101, and a dielectric layer 201 provided on a portion of the substrate 101.

The filter device 11 is a ladder filter. In the present preferred embodiment, the filter device 11 is a band pass filter configured to allow, when a radio frequency signal is transmitted from a first terminal T1 to a second terminal T2, a frequency component in a predetermined frequency band (pass band) of the radio frequency signal in question to pass therethrough. Note that the filter device 11 functions as a similar band pass filter also when a radio frequency signal is transmitted from the second terminal T2 to the first terminal T1. Note that the filter device 11 may be a band elimination filter configured to attenuate a frequency component in a predetermined frequency band (stop band) of a radio frequency signal.

The substrate 101 is a substrate that is piezoelectric and has a principal surface parallel to the xy plane. In the present preferred embodiment, the substrate 101 is formed of lithium niobate single crystal, for example. Note that the substrate 101 may be configured to be piezoelectric in part. Specifically, the substrate 101 may include a multilayer body including, for example, a support substrate, a thin piezoelectric film (piezoelectric material) provided on the surface, and a film different from the thin piezoelectric film in question in acoustic velocity.

On the principal surface of the substrate 101, the series line S30 and the parallel lines P41 to P43 are provided. The series line S30 is a transmission line through which radio frequency signals travel, for example, and connects the first terminal T1 and the second terminal T2 to each other. The series IDT electrodes 31 to 34 are each provided on the series line S30. In the present preferred embodiment, on the series line S30, the series IDT electrodes 31, 32, 33, and 34 are arranged in order of distance from the first terminal T1.

Specifically, the series IDT electrode 31 has a first end connected to the first terminal T1 and a second end. The series IDT electrode 32 has a first end connected to the second end of the series IDT electrode 31 and a second end. The series IDT electrode 33 has a first end connected to the second end of the series IDT electrode 32 and a second end. The series IDT electrode 34 has a first end connected to the second end of the series IDT electrode 33 and a second end connected to the second terminal T2.

The parallel lines P41 to P43 are each a transmission line through which radio frequency signals travel, for example, and branch off or extend from the series line S30. In the present preferred embodiment, the parallel line P41 branches off from a node N41 located between the series IDT electrode 31 and the series IDT electrode 32 on the series line S30. The parallel line P42 branches off from a node N42 located between the series IDT electrode 32 and the series IDT electrode 33 on the series line S30. The parallel line P43 branches off from a node N43 located between the series IDT electrode 33 and the series IDT electrode 34 on the series line S30.

The parallel IDT electrodes 41 to 43 are provided on the respective parallel lines P41 to P43. In the present preferred embodiment, the parallel IDT electrode 41 has a first end connected to the node N41 and a grounded second end. The parallel IDT electrode 42 has a first end connected to the node N42 and a grounded second end. The parallel IDT electrode 43 has a first end connected to the node N43 and a grounded second end.

At least one of the series IDT electrodes 31 to 34 is a first-type electrode 151. The dielectric layer 201 is provided between the first-type electrode 151 and the substrate 101. In the present preferred embodiment, the series IDT electrode 32 is the first-type electrode 151. Note that a configuration in which any of the series IDT electrodes 31, 33, and 34 is the first-type electrode 151 instead of the series IDT electrode 32 may be used. Further, a configuration in which two or more of the series IDT electrodes 31 to 34 are each the first-type electrode 151 may be used.

At least one of the series IDT electrodes 31 to 34 except the first-type electrode 151 and the parallel IDT electrodes 41 to 43 is a second-type electrode 152 directly formed on the substrate 101. Then, the remaining of the series IDT electrodes 31 to 34 and the parallel IDT electrodes 41 to 43 are each the first-type electrode 151 or the second-type electrode 152.

In the present preferred embodiment, the series IDT electrodes 31, 33, and 34 and the parallel IDT electrodes 41 to 43 are each the second-type electrode 152.

A series IDT electrode of the series IDT electrodes 31 to 34 that has electrode fingers at the largest pitch is the first-type electrode 151. In the present preferred embodiment, the pitch of the electrode fingers of the series IDT electrode 32 is larger than the pitch of the electrode fingers of each of the series IDT electrodes 31, 32, and 34.

Further, a resonator of resonators including the respective series IDT electrodes 31 to 34 that has the lowest anti-resonant frequency is a resonator including the first-type electrode 151. In the present preferred embodiment, the anti-resonant frequency of the resonator including the series IDT electrode 32 is lower than the anti-resonant frequencies of the resonators including the respective series IDT electrodes 31, 32, and 34. The details of pitches, the first-type electrode 151, resonators, and anti-resonant frequencies are described later.

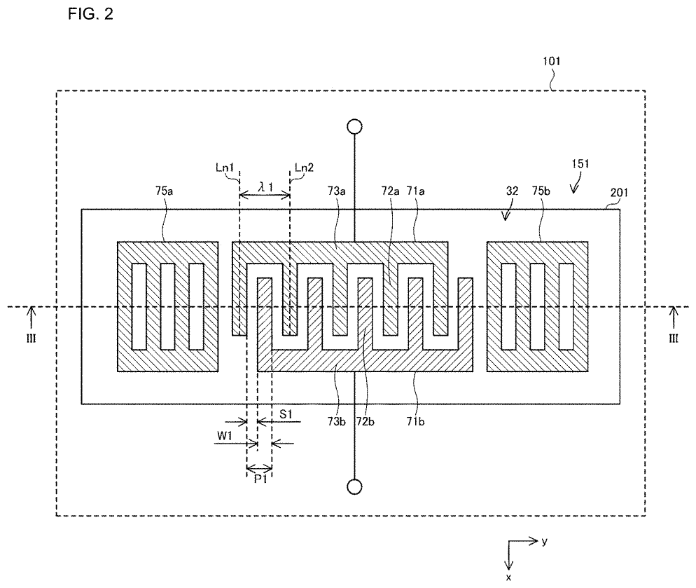

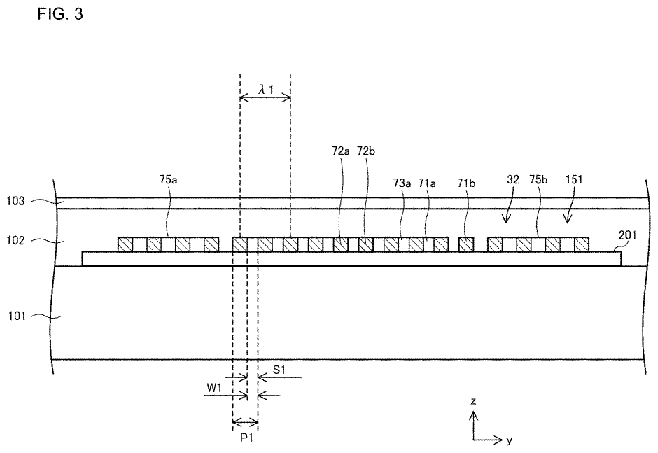

FIG. 2 is a schematic view illustrating the overview of the first-type electrode 151. FIG. 2 is a plan view illustrating the series IDT electrode 32, which serves as an example of the first-type electrode 151, the dielectric layer 201, and the substrate 101 seen from above. FIG. 3 is a sectional view taken along the cutting line III-III illustrated in FIG. 2. Note that FIG. 2 and FIG. 3 illustrate the example for illustrating the typical structure of the first-type electrode 151, but the shape, size, orientation, and the like of the first-type electrode 151 are not limited to this.

As illustrated in FIG. 2 and FIG. 3, the first-type electrode 151, the dielectric layer 201, and the substrate 101 function as a surface acoustic wave resonator (hereinafter sometimes referred to as “first-type resonator”). The first-type electrode 151 includes comb-like electrodes 71a and 71b and reflectors 75a and 75b. The comb-like electrodes 71a and 71b are hereinafter sometimes collectively referred to as “comb-like electrode 71”. The comb-like electrode 71 is a terminal. The comb-like electrode 71a has four electrode fingers 72a parallel to each other and a busbar electrode 73a connecting the four electrode fingers 72a to each other. Note that, in the present preferred embodiment, the four electrode fingers are illustrated, but the number of electrode fingers is not limited to four and the number of electrode fingers may be three or less or five or more.

In the present preferred embodiment, the busbar electrode 73a of the comb-like electrode 71a has a shape extending substantially in parallel to the y-axis direction. The electrode finger 72a has a shape extending substantially in parallel to the x-axis direction and has a −x-axis-side end portion connected to the busbar electrode 73a. The intervals between the electrode fingers 72a are even intervals, for example.

The comb-like electrode 71b has substantially the same shape as the comb-like electrode 71a and faces in the opposite direction to that of the comb-like electrode 71a, for example. That is, a busbar electrode 73b of the comb-like electrode 71b is located on the +x-axis side of the comb-like electrode 71a and has a shape extending substantially in parallel to the y-axis direction. An electrode finger 72b has a shape extending substantially in parallel to the x-axis direction and has a +x-axis-side end portion connected to the busbar electrode 73b. The intervals between the electrode fingers 72b are even intervals. “Even intervals” herein include errors due to manufacturing variations.

The comb-like electrodes 71a and 71b are arranged in orientations that make the four electrode fingers 72a and the four electrode fingers 72b be interdigitated with each other and the busbar electrodes 73a and 73b face each other. An acoustic wave generated by the first-type electrode 151 propagates along the y-axis direction orthogonal to the direction in which the electrode fingers 72a and the electrode fingers 72b extend, that is, the x-axis direction.

The reflectors 75a and 75b each have a plurality of electrode fingers parallel to each other and a busbar electrode connecting the plurality of electrode fingers in question to each other and are provided at the respective ends in the acoustic wave propagation direction of the comb-like electrodes 71a and 71b. The reflectors 75a and 75b have the same shape, for example.

Here, with regard to the two adjacent electrode fingers 72a, a distance between a line Ln1 passing through the center of the line width of one of the electrode fingers 72a and a line Ln2 passing through the center of the line width of the other of the electrode fingers 72a is defined as a wavelength λ1 of the comb-like electrode 71a. Note that since the comb-like electrode 71b has the same shape as the comb-like electrode 71a, the wavelength of the comb-like electrode 71b is the same as the wavelength λ1 of the comb-like electrode 71a.

Further, a pitch P1 of the electrode fingers 72a and 72b is defined as a value obtained by multiplying the wavelength λ1 by ½. When the line width of the electrode finger 72b is denoted by W1 and a space width between the electrode finger 72a and the electrode finger 72b adjacent to each other is denoted by S1, the pitch of the electrode fingers 72a is expressed by (W1+S1).

Note that, in the present preferred embodiment, the configuration in which the intervals between the electrode fingers 72a are even intervals has been described, but a configuration in which the intervals between the electrode fingers 72a are not even intervals may be used. In this case, for example, the wavelength of each pair of the two adjacent electrode fingers 72a may be obtained and a value of those wavelengths, such as average value or center value, may be calculated as the wavelength λ1 of the comb-like electrode 71a. The pitch P1 of the electrode fingers 72a and 72b can be obtained by multiplying the wavelength λ1 by ½.

The resonant frequency and anti-resonant frequency of the first-type resonator are changed depending on the pitch P1. Specifically, for example, as the pitch P1 is increased, the resonant frequency and anti-resonant frequency of the first-type resonator are decreased and as the pitch P1 is decreased, the resonant frequency and anti-resonant frequency of the first-type resonator are increased. The details of resonant frequencies are described later.

As illustrated in FIG. 3, the dielectric layer 201 is provided on the +z-axis side of the substrate 101. With the dielectric layer 201 formed at an appropriately selected thickness with an appropriately selected material, the electromechanical coupling coefficient and frequency characteristics of the first-type resonator can be adjusted. The adjustment of electromechanical coupling coefficients and frequency characteristics is described later.

The first-type electrode 151 is formed on the +z-axis side of the dielectric layer 201. A protective layer 102 is provided on the +z-axis side of the substrate 101 to cover the dielectric layer 201 and the first-type electrode 151. A protective layer 103 is provided on the +z-axis side of the protective layer 102. The protective layer 102 is formed of silicon dioxide (SiO2), for example. The protective layer 103 is formed of silicon nitride (SiN), for example. The protective layers 102 and 103 have functions of protecting the first-type electrode 151 from the external environment, adjusting the frequency temperature characteristics, and increasing the moisture resistance.

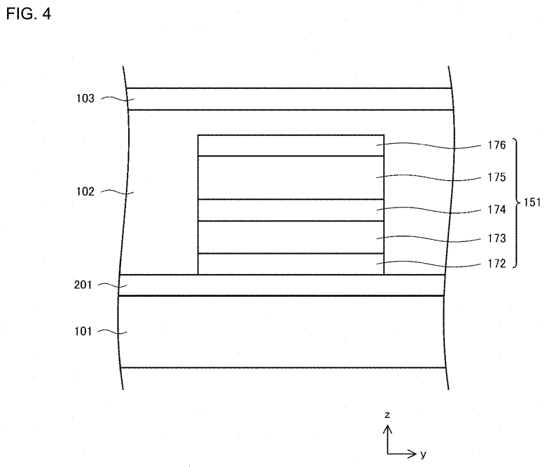

FIG. 4 is a schematic view illustrating the cross section of the first-type electrode 151. As illustrated in FIG. 4, the first-type electrode 151 includes metal films 172, 173, 174, 175, and 176 stacked in order toward the +z-axis side.

The metal film 172 is formed of an alloy of nickel and chromium (NiCr), for example. The metal film 173 is formed of platinum (Pt), for example. The metal film 174 is formed of titanium (Ti), for example. The metal film 175 is formed of an alloy of aluminum and copper (AlCu), for example. The metal film 176 is formed of titanium (Ti), for example.

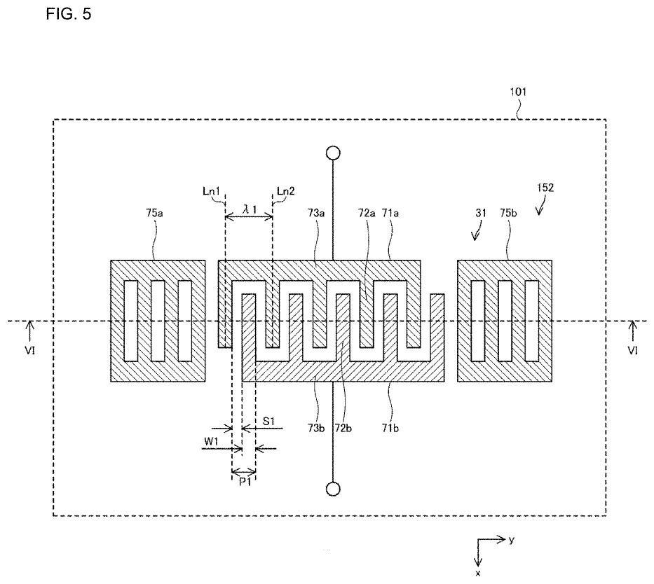

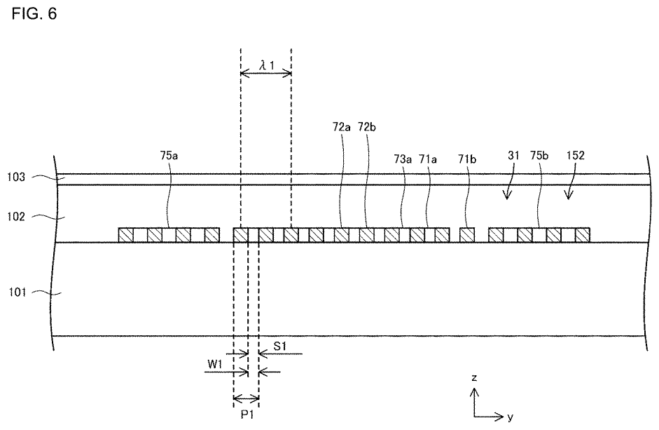

FIG. 5 is a schematic view illustrating the overview of the second-type electrode 152. FIG. 5 is a plan view illustrating the series IDT electrode 31, which serves as an example of the second-type electrode 152, and the substrate 101 seen from above. FIG. 6 is a sectional view taken along the cutting line VI-VI illustrated in FIG. 5. Note that FIG. 5 and FIG. 6 illustrate the example for illustrating the typical structure of the second-type electrode 152, but the shape, size, orientation, and the like of the second-type electrode 152 are not limited to this.

As illustrated in FIG. 5 and FIG. 6, the second-type electrode 152 and the substrate 101 function as a surface acoustic wave resonator (hereinafter sometimes referred to as “second-type resonator”). The second-type electrode 152 includes the comb-like electrodes 71a and 71b and the reflectors 75a and 75b. The comb-like electrodes 71a and 71b and the reflectors 75a and 75b included in the second-type electrode 152 are similar to the comb-like electrodes 71a and 71b and the reflectors 75a and 75b illustrated in FIG. 2 and FIG. 3, respectively.

As illustrated in FIG. 6, the second-type electrode 152 is directly formed on the +z-axis side of the substrate 101. The protective layer 102 is provided on the +z-axis side of the substrate 101 to cover the second-type electrode 152. The protective layer 103 is provided on the +z-axis side of the protective layer 102. The protective layers 102 and 103 are similar to the protective layers 102 and 103 illustrated in FIG. 2 and FIG. 3, respectively. The second-type electrode 152 includes, like the first-type electrode 151 illustrated in FIG. 4, the metal films 172, 173, 174, 175, and 176 stacked in order toward the +z-axis side.

### Action and Effect

As illustrated in FIG. 3, the electromechanical coupling coefficient of the first-type resonator formed of the first-type electrode 151, the dielectric layer 201, and the substrate 101 is increased as the thickness of the dielectric layer 201 is decreased. In short, the electromechanical coupling coefficient of the first-type resonator can be adjusted by adjusting the thickness of the dielectric layer 201.

Then, the electromechanical coupling coefficient of the second-type resonator (see FIG. 6) in which the dielectric layer 201 is not provided is larger than the electromechanical coupling coefficient of the first-type resonator.

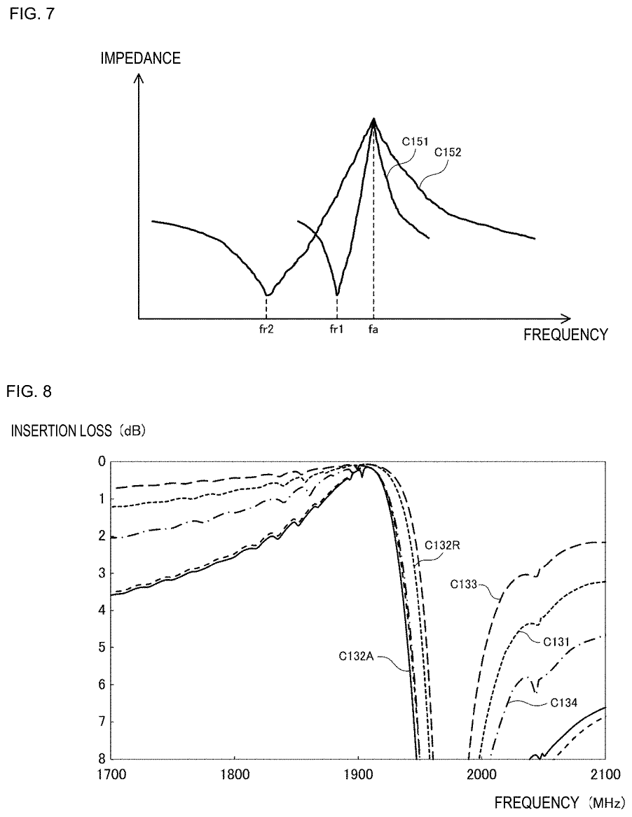

FIG. 7 is a diagram illustrating frequency-dependent changes in impedance between the terminals of a first-type resonator and impedance between the terminals of a second-type resonator. Note that, in FIG. 7, the horizontal axis indicates frequency and the vertical axis indicates impedance.

As illustrated in FIG. 7, a frequency-dependent change in impedance between the terminals of the first-type resonator is indicated by a curve C151. A frequency-dependent change in impedance between the terminals of the second-type resonator is indicated by a curve C152.

In the curves C151 and C152, the anti-resonant frequency of the first-type resonator and the anti-resonant frequency of the second-type resonator are both fa. Note that this is for simplifying the description, and the anti-resonant frequency of the first-type resonator and the anti-resonant frequency of the second-type resonator can be set to any value.

A resonant frequency fr1 of the first-type resonator is higher than a resonant frequency fr2 of the second-type resonator. In short, a difference between the anti-resonant frequency fa and the resonant frequency fr1 (hereinafter sometimes referred to as “resonant frequency difference”) of the first-type resonator is smaller than the resonant frequency difference of the second-type resonator, that is, a difference between the anti-resonant frequency fa and the resonant frequency fr2.

Then, as indicated by the curves C151 and C152, the frequency-dependent change in impedance between the terminals of the first-type resonator is steeper than the frequency-dependent change in impedance between the terminals of the second-type resonator.

In the following, the second-type resonator including the series IDT electrode 31, 33, or 34 in the filter device 11 illustrated in FIG. 1 is sometimes referred to as “series resonator 131, 133, or 134”. Further, the first-type resonator including the series IDT electrode 32 is sometimes referred to as “series resonator 132A”.

FIG. 8 is a diagram illustrating exemplary frequency characteristics of each series resonator. Note that, in FIG. 8, the horizontal axis indicates frequency in megahertz (MHz) and the vertical axis indicates insertion loss in decibel (dB).

As illustrated in FIG. 8, curves C131, C132A, C133, and C134 indicate frequency-dependent changes in insertion loss of the respective series resonators 131, 132A, 133, and 134 (see FIG. 1). A curve C132R indicates a frequency-dependent change in insertion loss of a first reference series resonator provided in the filter device 11 instead of the series resonator 132A. Here, the first reference series resonator is a resonator including the series IDT electrode 32 directly formed on the substrate 101 unlike the series resonator 132A.

From a comparison between the curve C132A and the curves C131, C132R, C133, and C134, it is discovered that the resonant frequency of the series resonator 132A (see FIG. 1) is lowest.

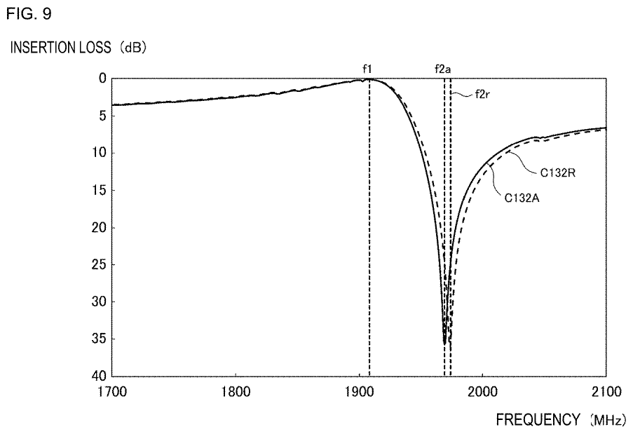

FIG. 9 is a diagram illustrating exemplary frequency characteristics of the series resonator 132A and a first reference series resonator. Note that FIG. 9 can be read in a similar manner to FIG. 8. Here, the width of a band is defined as a difference between the frequencies of a resonator with the lowest insertion loss value and an insertion loss value greater than the lowest insertion loss value by 3 dB.

As illustrated in FIG. 9, the anti-resonant frequency and resonant frequency of the first reference series resonator are f2r and f1, respectively (see curve C132R). Further, the anti-resonant frequency and resonant frequency of the series resonator 132A are f2a and f1, respectively (see curve C132A). Here, the frequency f2r is higher than the frequency f2a.

The resonant frequency difference of a resonator having a small coupling coefficient is smaller than the resonant frequency difference of a resonator having a large coupling coefficient. Since the coupling coefficient of the series resonator 132A is smaller than the coupling coefficient of the first reference series resonator, the resonant frequency difference of the series resonator 132A (difference between f2a and f1) is smaller than the resonant frequency difference of the first reference series resonator (difference between f2r and f1).

In this way, with the dielectric layer 201 provided between the series IDT electrode 32 and the substrate 101 to achieve a small coupling coefficient, the slope of the curve C132A between the frequencies f1 and f2a can be steeper than the slope of the curve C132R between the frequencies f1 and f2r.

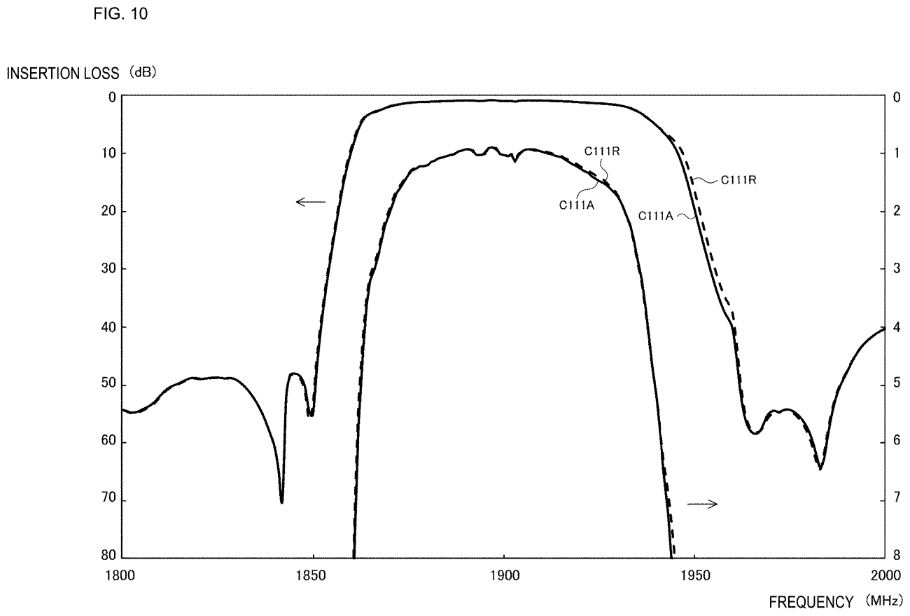

FIG. 10 is a diagram illustrating exemplary frequency characteristics of the filter device 11 and a first reference filter device. Here, the first reference filter device corresponds to the filter device 11 (see FIG. 1) in which the first reference series resonator is provided instead of the series resonator 132A. Note that FIG. 10 can be read in a similar manner to FIG. 8.

As illustrated in FIG. 10, a curve C111A, which is the solid line, indicates a frequency-dependent change in insertion loss between the first terminal T1 and the second terminal T2 in the filter device 11 (see FIG. 1). A curve C111R, which is the dotted line, indicates a frequency-dependent change in insertion loss between the first terminal T1 and the second terminal T2 in the first reference filter device.

The filter device 11 and the first reference filter device each function as a band pass filter. The frequency-dependent change of the curve C111A in a transition region between a pass band (1860 to 1950 MHz) and a high frequency-side stop band is steeper than the frequency-dependent change of the curve C111R in the transition region in question.

With the first-type electrode 151 and the second-type electrode 152 formed on the same substrate 101, while the pass band of the filter can be widened with the second-type electrode 152 having a large coupling coefficient, the degree of the steepness at the end portion of the pass band in question can be increased with the first-type electrode 151 having a small coupling coefficient.

That is, the filter device 11 that has a wide pass band and ensures the steepness near the pass band in question and the stop band can be provided. Further, as compared to a case where a first-type resonator and a second-type resonator are formed on separate substrates, the resonators can be arranged in an aggregated manner so that the size of the filter device 11 can be reduced.

Further, the temperature coefficient of frequency of the first-type electrode 151 is smaller than the temperature coefficient of frequency of the second-type electrode 152. That is, in the series resonator 132A, as compared to the first reference series resonator, changes in resonant frequency and anti-resonant frequency due to a temperature change can be prevented. With this, the filter device 11 can favorably function as a filter over a wide environmental temperature range.

Further, when electric power is applied to a resonator, a portion of the electric power is converted into heat to raise the temperature of the resonator. With a temperature rise, the frequency characteristics of the first reference series resonator are changed more largely than the frequency characteristics of the series resonator 132A. Thus, in the first reference series resonator, when electric power is applied to raise the temperature, the frequency characteristics are largely shifted from those at room temperature and more electric power is converted into heat due to the large shift. In short, the first reference series resonator gets hot more easily than the series resonator 132A. Since a resonator at high temperature tends to be vulnerable to electrical breakdown, the first reference series resonator has a higher risk of the occurrence of electrical breakdown than the series resonator 132A. In contrast to this, in the series resonator 132A, a temperature rise due to the application of electric power can be prevented so that the risk of the occurrence of electrical breakdown can be reduced, that is, the electric power handling capability can be improved.

Note that although, with the filter device 11, the configuration in which the four series IDT electrodes are provided on the series line S30 has been described, the present invention is not limited to this. A configuration in which three or less or five or more series IDT electrodes are provided on the series line S30 may be used.

Further, although, with the filter device 11, the configuration in which the three parallel lines each branch off from the series line S30 has been described, the present invention is not limited to this. The filter device 11 may have a configuration in which two or less or four or more parallel lines each branch off from the series line S30. In this case, one or more parallel IDT electrodes are provided on each parallel line.

### Second Preferred Embodiment

A filter device according to a second preferred embodiment is described. In the second and following preferred embodiments, the description of matters common to those in the first preferred embodiment is omitted and only different points are described. In particular, similar actions and effects provided by similar configurations are not mentioned one by one in each preferred embodiment.

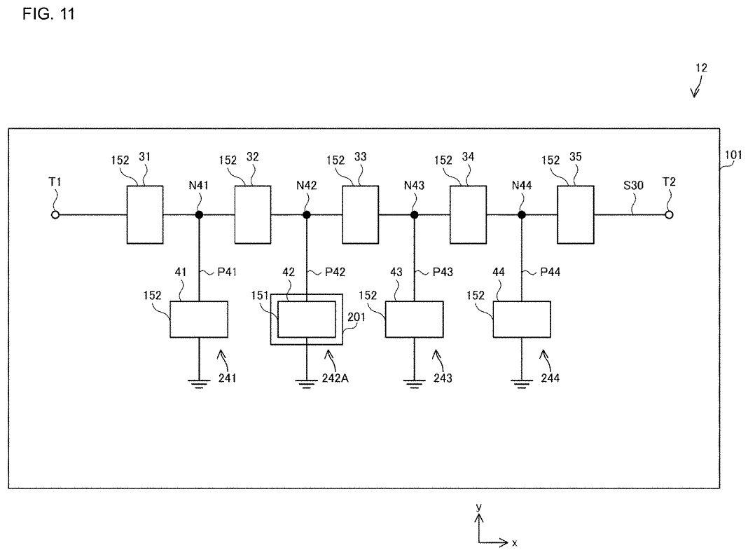

FIG. 11 is a diagram illustrating the circuit configuration of a filter device 12. As illustrated in FIG. 11, the filter device 12 according to the second preferred embodiment is different from the filter device 11 according to the first preferred embodiment in that the first-type electrode 151 is provided on the parallel line.

In the filter device 12, as compared to the filter device 11 illustrated in FIG. 1, the dielectric layer 201 is provided between the parallel IDT electrode 42 and the substrate 101 while the dielectric layer 201 is not provided between the series IDT electrode 32 and the substrate 101, and a series IDT electrode 35 and a parallel IDT electrode 44 are further included. In short, the series IDT electrode 32 is the second-type electrode 152 and the parallel IDT electrode 42 is the first-type electrode 151.

Note that a configuration in which any of the parallel IDT electrodes 41, 43, and 44 is the first-type electrode 151 instead of the parallel IDT electrode 42 may be used. Further, a configuration in which two or more of the parallel IDT electrodes 41 to 44 are each the first-type electrode 151 may be used.

The filter device 12 is a band pass filter. Note that the filter device 12 may be a band elimination filter.

A parallel IDT electrode of the parallel IDT electrodes 41 to 44 that has electrode fingers at the smallest pitch is the first-type electrode 151. In the present preferred embodiment, the pitch of the electrode fingers of the parallel IDT electrode 42 is smaller than the pitch of the electrode fingers of each of the parallel IDT electrodes 41, 43, and 44.

Further, a resonator of resonators including the respective parallel IDT electrodes 41 to 44 that has the highest resonant frequency is a resonator including the first-type electrode 151. In the present preferred embodiment, the resonant frequency of the resonator including the parallel IDT electrode 42 is higher than the resonant frequencies of the resonators including the respective parallel IDT electrodes 41, 43, and 44.

### Action and Effect

In the following, the second-type resonator including the parallel IDT electrode 41, 43, or 44 in the filter device 12 illustrated in FIG. 11 is sometimes referred to as “parallel resonator 241, 243, or 244”. Further, the first-type resonator including the parallel IDT electrode 42 is sometimes referred to as “parallel resonator 242A”.

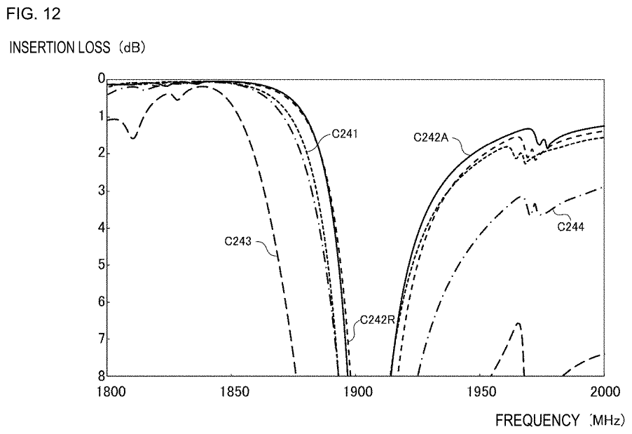

FIG. 12 is a diagram illustrating exemplary frequency characteristics of each parallel resonator. Note that FIG. 12 can be read in a similar manner to FIG. 8.

As illustrated in FIG. 12, curves C241, C242A, C243, and C244 indicate frequency-dependent changes in insertion loss of the respective parallel resonators 241, 242A, 243, and 244 (see FIG. 11). A curve C242R indicates a frequency-dependent change in insertion loss of a first reference parallel resonator provided in the filter device 12 instead of the parallel resonator 242A. Here, the first reference parallel resonator is a resonator including the parallel IDT electrode 42 directly formed on the substrate 101 unlike the parallel resonator 242A.

In FIG. 12, when a portion with a large insertion loss indicates an anti-resonant frequency, a portion with a small insertion loss indicates a resonant frequency. In that case, from a comparison between the curve C242A and the curves C241, C242R, C243, and C244, it is discovered that the resonant frequency of the parallel resonator 242A is highest.

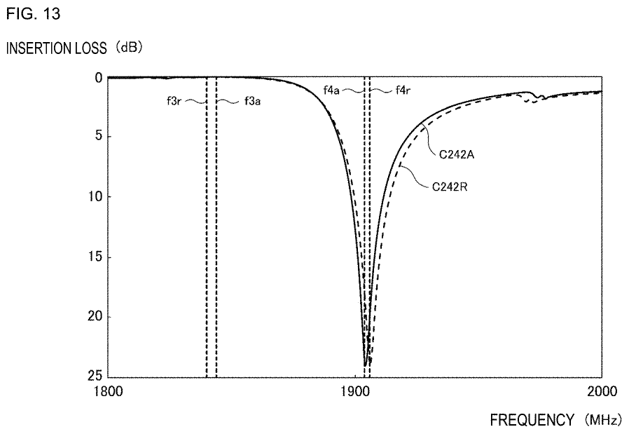

FIG. 13 is a diagram illustrating exemplary frequency characteristics of the parallel resonator 242A and a first reference parallel resonator. Note that FIG. 13 can be read in a similar manner to FIG. 8.

As illustrated in FIG. 13, the anti-resonant frequency and resonant frequency of the first reference parallel resonator are f4r and f3r, respectively (see curve C242R). Further, the anti-resonant frequency and resonant frequency of the parallel resonator 242A are f4a and f3a, respectively (see curve C242A). Here, the frequency f4r is higher than the frequency f4a. The frequency f3r is lower than the frequency f3a.

Since the coupling coefficient of the parallel resonator 242A is smaller than the coupling coefficient of the first reference parallel resonator, the resonant frequency difference of the parallel resonator 242A (difference between f4a and f3a) is smaller than the resonant frequency difference of the first reference parallel resonator (difference between f4r and f3r).

In this way, with the dielectric layer 201 provided between the parallel IDT electrode 42 and the substrate 101 to achieve a small coupling coefficient, the slope of the curve C242A between the frequencies f3a and f4a can be steeper than the slope of the curve C242R between the frequencies f3r and f4r.

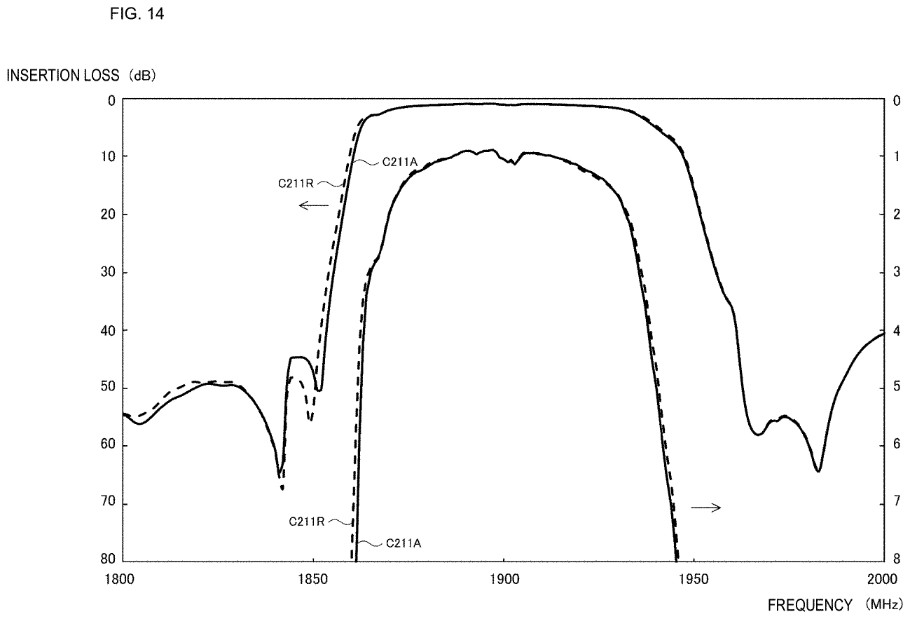

FIG. 14 is a diagram illustrating exemplary frequency characteristics of the filter device 12 and a second reference filter device. Here, the second reference filter device corresponds to the filter device 12 (see FIG. 11) in which the first reference parallel resonator is provided instead of the parallel resonator 242A. Note that FIG. 14 can be read in a similar manner to FIG. 8.

As illustrated in FIG. 14, a curve C211A, which is the solid line, indicates a frequency-dependent change in insertion loss between the first terminal T1 and the second terminal T2 in the filter device 12. A curve C211R, which is the dotted line, indicates a frequency-dependent change in insertion loss between the first terminal T1 and the second terminal T2 in the second reference filter device.

The filter device 12 and the second reference filter device each function as a band pass filter. The frequency-dependent change of the curve C211A in a transition region between a pass band (1860 to 1940 MHz) and a low frequency-side stop band is steeper than the frequency-dependent change of the curve C211R in the transition region in question.

That is, with the first-type electrode 151 and the second-type electrode 152 formed on the same substrate 101, the filter device 12 that has a wide pass band and ensures the steepness near the pass band in question and the stop band can be provided.

### Third Preferred Embodiment

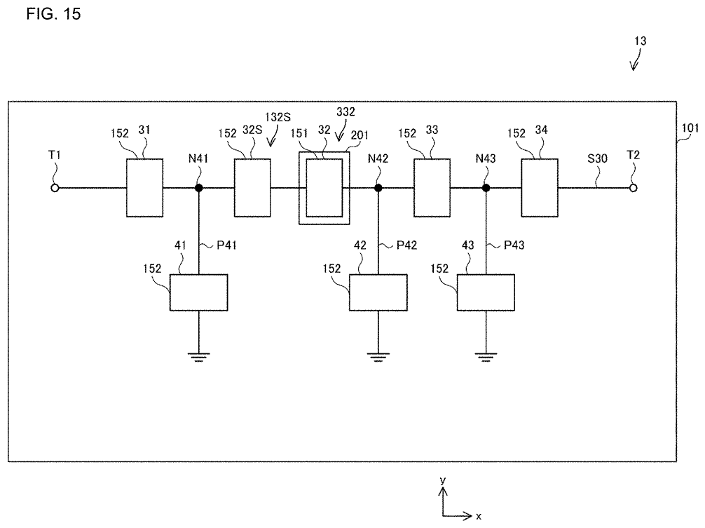

A filter device according to a third preferred embodiment is described. FIG. 15 is a diagram illustrating the circuit configuration of a filter device 13. As illustrated in FIG. 15, the filter device 13 according to the third preferred embodiment is different from the filter device 11 according to the first preferred embodiment in that the first-type electrode 151 and the second-type electrode 152 are connected in series to each other on the series line S30 between the parallel lines P41 and P42.

The filter device 13 further includes, as compared to the filter device 11 illustrated in FIG. 1, a series IDT electrode 32S (series connection electrode). The series IDT electrode 32S is a first series IDT electrode connected in series to the first-type electrode 151, which is provided on the series line S30, without the interposition of a node at which a parallel line branches off.

Specifically, the series IDT electrode 32S is the second-type electrode 152 provided on the series line S30. The series IDT electrode 32S has a first end connected to the second end of the series IDT electrode 31 and a second end. The first end of the series IDT electrode 32 is connected to the second end of the series IDT electrode 32S without the interposition of a node at which a parallel line branches off.

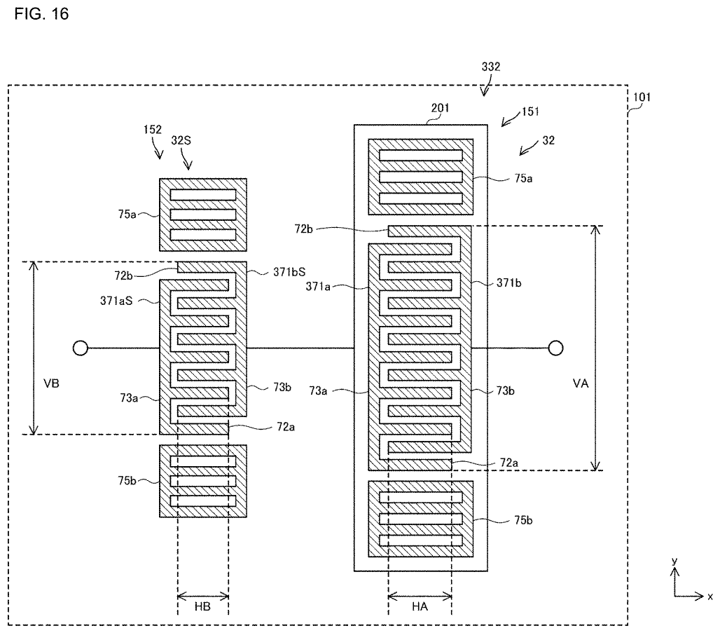

FIG. 16 is a schematic view illustrating the overview of the series IDT electrodes 32 and 32S. FIG. 16 is a plan view illustrating the series IDT electrodes 32 and 32S, the dielectric layer 201, and the substrate 101 seen from above.

As illustrated in FIG. 16, in the plan view of the substrate 101, the size of the series IDT electrode 32 (first-type electrode 151) connected in series to the series IDT electrode 32S is larger than the size of the series IDT electrode 32S.

In the present preferred embodiment, the size of the series IDT electrode 32 corresponds to the area of the series IDT electrode 32 except the areas of the reflectors 75a and 75b. Specifically, the area of the series IDT electrode 32 is the area of the alternating region of comb-like electrodes 371a and 371b, for example.

Specifically, the alternating region of the comb-like electrodes 371a and 371b has a rectangular shape. The length of the long side of the alternating region in question and the length of the short side thereof are a vertical length VA and a horizontal length HA, respectively. In short, the area of the alternating region in question takes a value obtained by multiplying the vertical length VA by the horizontal length HA.

Here, the vertical length VA is a length between, of the plurality of electrode fingers 72a of the comb-like electrode 371a and the plurality of electrode fingers 72b of the comb-like electrode 371b, the outer edge in the outermost portion of the electrode finger provided at one end and the outer edge in the outermost portion of the electrode finger provided at the other end when seen from the direction in which the electrode fingers 72a and the electrode fingers 72b are aligned (y axis direction). The horizontal length HA is the length of a portion in which the electrode fingers 72a of the comb-like electrode 371a and the electrode fingers 72b of the comb-like electrode 371b overlap each other when seen from the direction in which the electrode fingers 72a of the comb-like electrode 371a and the electrode fingers 72b of the comb-like electrode 371b are aligned (y-axis direction).

In a similar manner, the size of the series IDT electrode 32S corresponds to the area of the alternating region of comb-like electrodes 371aS and 371bS, for example.

Specifically, the alternating region of the comb-like electrodes 371aS and 371bS has a rectangular shape. The length of the long side of the alternating region in question and the length of the short side thereof are a vertical length VB and a horizontal length HB, respectively. In short, the area of the alternating region in question takes a value obtained by multiplying the vertical length VB by the horizontal length HB.

Here, the vertical length VB is a length between, of the plurality of electrode fingers 72a of the comb-like electrode 371aS and the plurality of electrode fingers 72b of the comb-like electrode 371bS, the outer edge in the outermost portion of the electrode finger provided at one end and the outer edge in the outermost portion of the electrode finger provided at the other end when seen from the direction in which the electrode fingers 72a and the electrode fingers 72b are aligned (y axis direction). The horizontal length HB is the length of a portion in which the electrode fingers 72a of the comb-like electrode 371aS and the electrode fingers 72b of the comb-like electrode 371bS overlap each other when seen from the direction in which the electrode fingers 72a of the comb-like electrode 371aS and the electrode fingers 72b of the comb-like electrode 371bS are aligned (y-axis direction).

The value obtained by multiplying the vertical length VA by the horizontal length HA, that is, the area of the alternating region of the comb-like electrodes 371a and 371b is larger than the value obtained by multiplying the vertical length VB by the horizontal length HB, that is, the area of the alternating region of the comb-like electrodes 371aS and 371bS.

Note that although the configuration in which the size of each of the series IDT electrodes 32 and 32S takes the value obtained by multiplying the vertical length by the horizontal length has been described, the present invention is not limited to this. The size of the series IDT electrode 32 may correspond to the area of the outline of the comb-like electrodes 371a and 371b, for example. The size of the series IDT electrode 32S may also correspond to the area of the outline of the comb-like electrodes 371aS and 371bS, for example.

Further, although the configuration in which the series IDT electrode 32S is the second-type electrode 152 has been described, the present invention is not limited to this. A configuration in which the series IDT electrode 32S is the first-type electrode 151 may be used.

### Action and Effect

In the following, the first-type resonator including the series IDT electrode 32 that is the first-type electrode 151 in the filter device 13 illustrated in FIG. 15 is sometimes referred to as “series resonator 332”. The second-type resonator including the series IDT electrode 32S is sometimes referred to as “series resonator 132S”. Further, the second-type resonator including the series IDT electrode 32 that is not the first-type electrode 151 but the second-type electrode 152 in the filter device 13 is sometimes referred to as “second reference series resonator”.

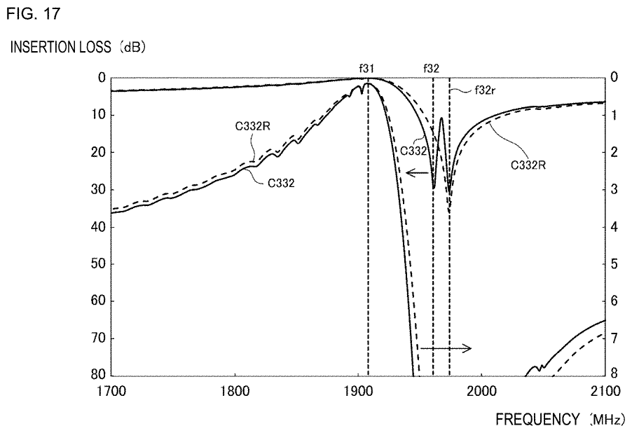

FIG. 17 is a diagram illustrating exemplary frequency characteristics of the series resonator 332 and a second reference series resonator. Note that FIG. 17 can be read in a similar manner to FIG. 8.

As illustrated in FIG. 17, a curve C332, which is the solid line, indicates a frequency-dependent change in insertion loss of the series resonator 332. A curve C332R, which is the dotted line, indicates a frequency-dependent change in insertion loss of the second reference series resonator.

The anti-resonant frequency and resonant frequency of the second reference series resonator are f32r and f31, respectively (see curve C332R). Further, the anti-resonant frequency and resonant frequency of the series resonator 332 are f32 and f31, respectively (see curve C332). Here, the frequency f32r is higher than the frequency f32.

Since the coupling coefficient of the series resonator 332 is smaller than the coupling coefficient of the second reference series resonator, the resonant frequency difference of the series resonator 332 (difference between f32 and f31) is smaller than the resonant frequency difference of the second reference series resonator (difference between f32r and f31).

In this way, with the dielectric layer 201 provided between the series IDT electrode 32 and the substrate 101 to achieve a small coupling coefficient, the slope of the curve C332 between the frequencies f31 and f32 can be steeper than the slope of the curve C332R between the frequencies f31 and f32r.

With the series resonator 332 and the series resonator 132S connected in series to each other, a wide band and steep filter characteristics can be realized. Further, for example, when the series IDT electrodes 32S and 32 (see FIG. 15) are provided instead of the series IDT electrode 32 (see FIG. 1), while the capacitance is maintained, the area of each of the series IDT electrodes 32S and 32 can be increased to distribute stress on input electric power. With this, in the filter device 13, the electric power handling capability can be improved.

### Fourth Preferred Embodiment

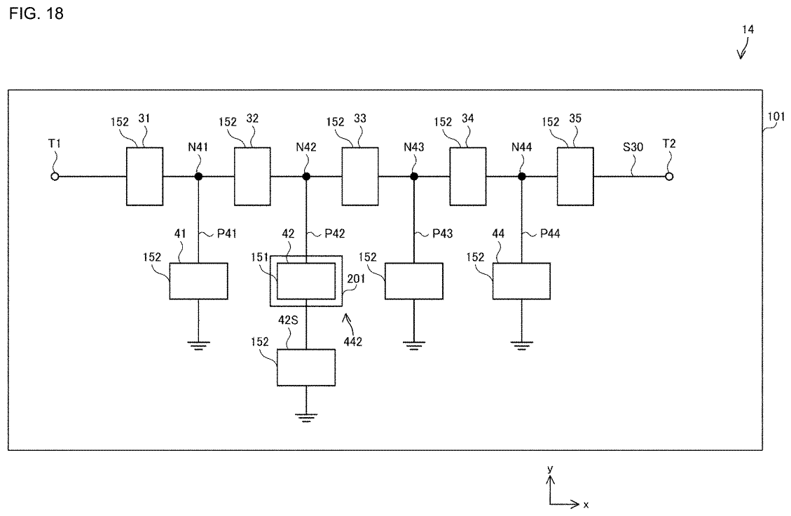

A filter device according to a fourth preferred embodiment is described. FIG. 18 is a diagram illustrating the circuit configuration of a filter device 14. As illustrated in FIG. 18, the filter device 14 according to the fourth preferred embodiment is different from the filter device 12 according to the second preferred embodiment in that the first-type electrode 151 and the second-type electrode 152 are connected in series to each other on the parallel line P42.

The filter device 14 further includes, as compared to the filter device 12 illustrated in FIG. 11, a parallel IDT electrode 42S (series connection electrode). The parallel IDT electrode 42S is a first parallel IDT electrode connected in series to the first-type electrode 151 provided on the parallel line P42.

Specifically, the parallel IDT electrode 42S is the second-type electrode 152 provided on the parallel line P42. The parallel IDT electrode 42S has a first end connected to the second end of the parallel IDT electrode 42 and a grounded second end. The first-type resonator including the parallel IDT electrode 42 that is the first-type electrode 151 in the filter device 14 illustrated in FIG. 18 is hereinafter sometimes referred to as “parallel resonator 442”.

In the plan view of the substrate 101, the size of the parallel IDT electrode 42 (first-type electrode 151) connected in series to the parallel IDT electrode 42S is larger than the size of the parallel IDT electrode 42S.

Note that although the configuration in which the parallel IDT electrode 42S is the second-type electrode 152 has been described, the present invention is not limited to this. A configuration in which the parallel IDT electrode 42S is the first-type electrode 151 may be used.

### Fifth Preferred Embodiment

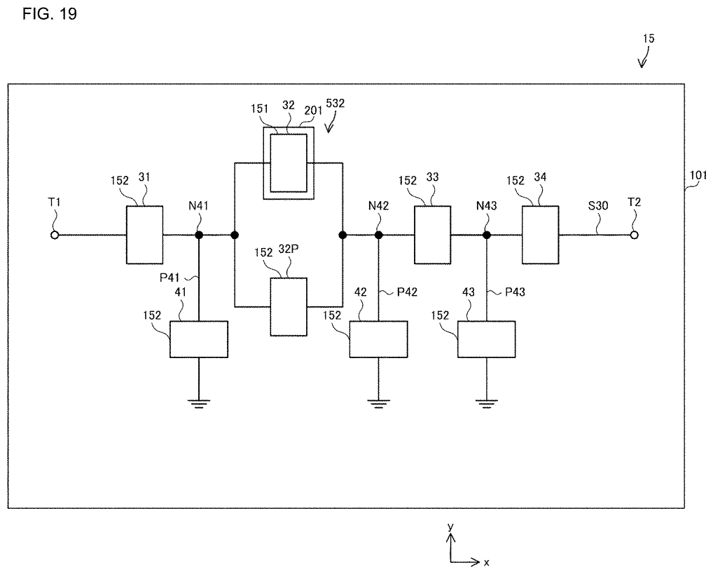

A filter device according to a fifth preferred embodiment is described. FIG. 19 is a diagram illustrating the circuit configuration of a filter device 15. As illustrated in FIG. 19, the filter device 15 according to the fifth preferred embodiment is different from the filter device 11 according to the first preferred embodiment in that the first-type electrode 151 and the second-type electrode 152 are connected in parallel to each other on the series line S30.

The filter device 15 further includes, as compared to the filter device 11 illustrated in FIG. 1, a series IDT electrode 32P (parallel connection electrode). The series IDT electrode 32P is a first series IDT electrode connected in parallel to the first-type electrode 151 provided on the series line S30.

Specifically, the series IDT electrode 32P is the second-type electrode 152 connected in parallel to the series IDT electrode 32. The series IDT electrode 32P has a first end connected to the first end of the series IDT electrode 32 and a second end connected to the second end of the series IDT electrode 32.

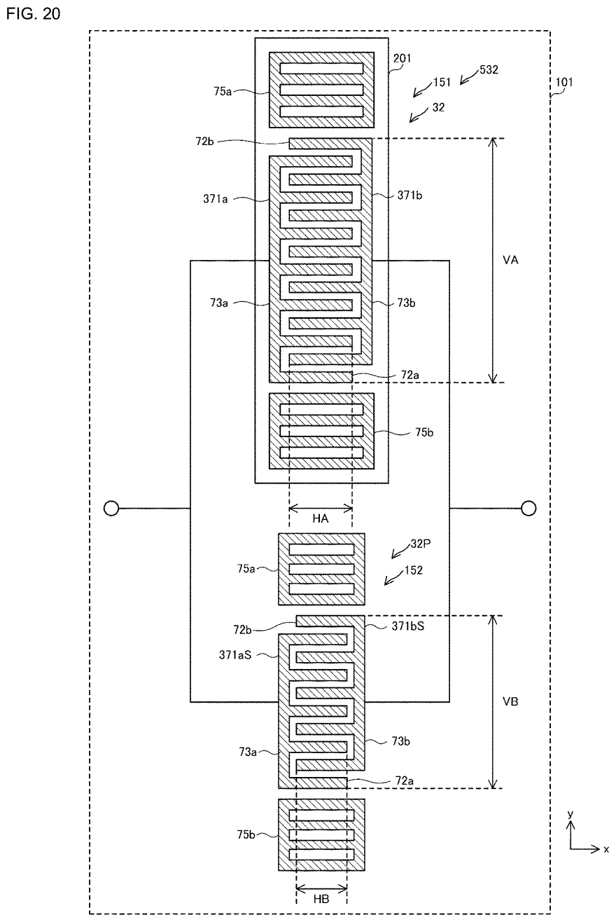

FIG. 20 is a schematic view illustrating the overview of the series IDT electrodes 32 and 32P. FIG. 20 is a plan view illustrating the series IDT electrodes 32 and 32P, the dielectric layer 201, and the substrate 101 seen from above.

As illustrated in FIG. 20, in the plan view of the substrate 101, the size of the series IDT electrode 32 (first-type electrode 151) connected in parallel to the series IDT electrode 32P is larger than the size of the series IDT electrode 32P.

In the present preferred embodiment, a value obtained by multiplying the vertical length VA by the horizontal length HA in the series IDT electrode 32 is larger than a value obtained by multiplying the vertical length VB by the horizontal length HB in the series IDT electrode 32P.

Note that although the configuration in which the series IDT electrode 32P is the second-type electrode 152 has been described, the present invention is not limited to this. A configuration in which the series IDT electrode 32P is the first-type electrode 151 may be used.

### Action and Effect

In the following, the first-type resonator including the series IDT electrode 32 that is the first-type electrode 151 in the filter device 15 illustrated in FIG. 19 is sometimes referred to as “series resonator 532”. Further, the second-type resonator including the series IDT electrode 32 that is not the first-type electrode 151 but the second-type electrode 152 in the filter device 15 is sometimes referred to as “third reference series resonator”.

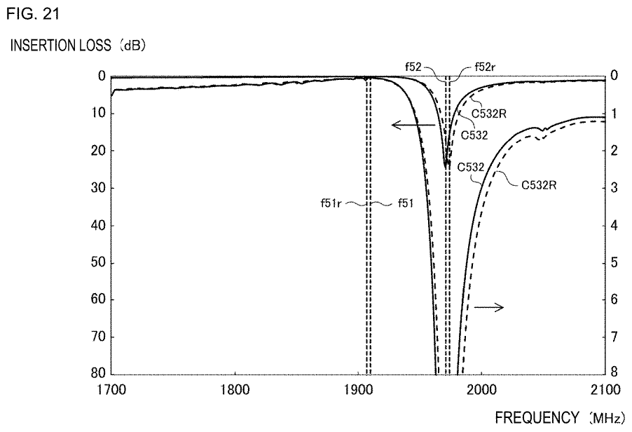

FIG. 21 is a diagram illustrating exemplary frequency-dependent changes in insertion loss of the series resonator 532 and a third reference series resonator. Note that FIG. 21 can be read in a similar manner to FIG. 8.

As illustrated in FIG. 21, a curve C532, which is the solid line, indicates a frequency-dependent change in insertion loss of the series resonator 532. A curve C532R, which is the dotted line, indicates a frequency-dependent change in insertion loss of the third reference series resonator.

The anti-resonant frequency and resonant frequency of the third reference series resonator are f52r and f51r, respectively (see curve C532R). Further, the anti-resonant frequency and resonant frequency of the series resonator 532 are f52 and f51, respectively (see curve C532). Here, the frequency f51r is lower than the frequency f51. The frequency f52r is higher than the frequency f52.

Since the coupling coefficient of the series resonator 532 is smaller than the coupling coefficient of the third reference series resonator, the resonant frequency difference of the series resonator 532 (difference between f52 and f51) is smaller than the resonant frequency difference of the third reference series resonator (difference between f52r and f51r).

In this way, with the dielectric layer 201 provided between the series IDT electrode 32 and the substrate 101 to achieve a small coupling coefficient, the slope of the curve C532 between the frequencies f51 and f52 can be steeper than the slope of the curve C532R between the frequencies f51r and f52r.

The series resonator 532 having such steep filter characteristics is provided to the filter device 15 so that the steepness at the end portion of the filter band of the filter device 15 can be increased.

Further, for example, when the series IDT electrodes 32P and 32 (see FIG. 19) are provided instead of the series IDT electrode 32 (see FIG. 1), the area of each of the series IDT electrodes 32P and 32 can be reduced while the capacitance is maintained. With this, in the filter device 15, the series IDT electrodes 32P and 32 can be easily laid out.

### Sixth Preferred Embodiment

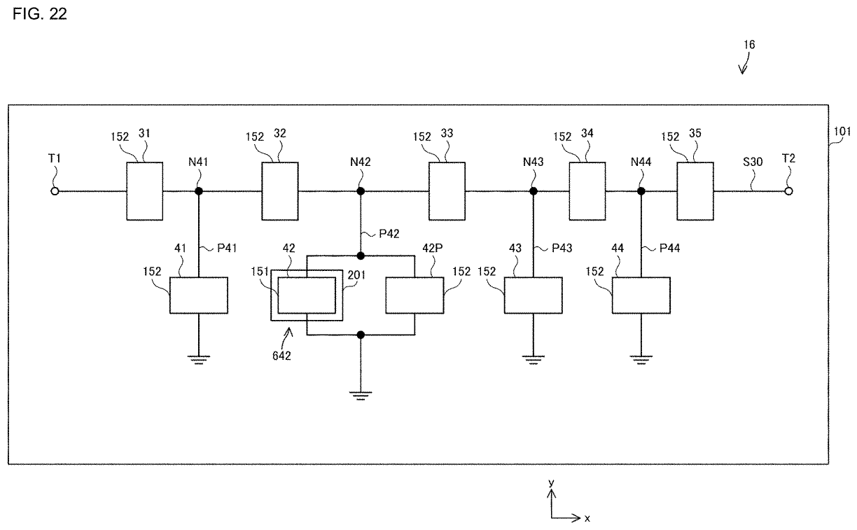

A filter device according to a sixth preferred embodiment is described. FIG. 22 is a diagram illustrating the circuit configuration of a filter device 16. As illustrated in FIG. 22, the filter device 16 according to the sixth preferred embodiment is different from the filter device 12 according to the second preferred embodiment in that the first-type electrode 151 and the second-type electrode 152 are connected in parallel to each other on the parallel line P42.

The filter device 16 further includes, as compared to the filter device 12 illustrated in FIG. 11, a parallel IDT electrode 42P (parallel connection electrode). The parallel IDT electrode 42P is a first parallel IDT electrode connected in parallel to the first-type electrode 151, which is provided on the parallel line P42, without the interposition of a first series IDT electrode.

Specifically, the parallel IDT electrode 42P is the second-type electrode 152 connected in parallel to the parallel IDT electrode 42. The parallel IDT electrode 42P has a first end connected to the first end of the parallel IDT electrode 42 and a second end connected to the second end of the parallel IDT electrode 42. The first-type resonator including the parallel IDT electrode 42 that is the first-type electrode 151 in the filter device 16 illustrated in FIG. 22 is hereinafter sometimes referred to as “parallel resonator 642”.

In the plan view of the substrate 101, the size of the parallel IDT electrode 42 (first-type electrode 151) connected in parallel to the parallel IDT electrode 42P is larger than the size of the parallel IDT electrode 42P.

Note that although the configuration in which the parallel IDT electrode 42P is the second-type electrode 152 has been described, the present invention is not limited to this. A configuration in which the parallel IDT electrode 42P is the first-type electrode 151 may be used.

### Seventh Preferred Embodiment

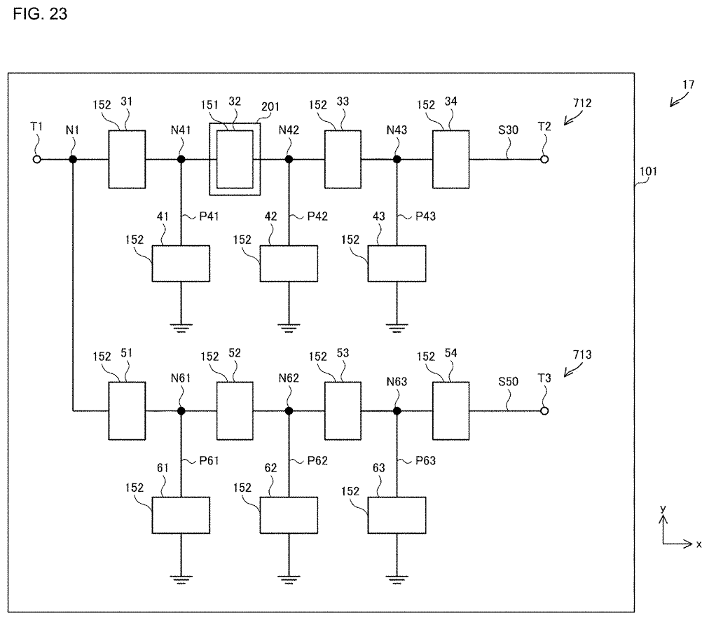

A filter device according to a seventh preferred embodiment is described. FIG. 23 is a diagram illustrating the circuit configuration of a filter device 17. As illustrated in FIG. 23, the filter device 17 according to the seventh preferred embodiment is different from the filter device 11 according to the first preferred embodiment in that a second filter is further provided.

The filter device 17 further includes, as compared to the filter device 11 illustrated in FIG. 1, a series line S50 (second series line), three parallel lines P61 to P63 (second parallel lines), four series IDT electrodes 51 to 54 (second series IDT electrodes), and three parallel IDT electrodes 61 to 63 (second parallel IDT electrodes).

The filter device 17 includes two ladder filters having the first terminal T1 as a common terminal. In the following, the ladder filter between the first terminal T1 and the second terminal T2 in the filter device 17 is sometimes referred to as “filter 712”. The ladder filter between the first terminal T1 and a third terminal T3 in the filter device 17 is sometimes referred to as “filter 713”.

In the present preferred embodiment, the filters 712 and 713 function as band elimination filters, for example. Note that the filters 712 and 713 may function as other filters such as band pass filters.

On the principal surface of the substrate 101, the series lines S30 and S50, the parallel lines P41 to P43, and the parallel lines P61 to P63 are provided. The series line S50 is a transmission line through which radio frequency signals travel, for example, and connects the first terminal T1 and the third terminal T3 to each other. In the present preferred embodiment, the series line S50 connects a node N1 provided between the first terminal T1 and the series IDT electrode 31 and the third terminal T3 to each other.

The series IDT electrodes 51 to 54 are each provided on the series line S50. In the present preferred embodiment, on the series line S50, the series IDT electrodes 51, 52, 53, and 54 are arranged in order of distance from the node N1.

Specifically, the series IDT electrode 51 has a first end connected to the node N1 and a second end. The series IDT electrode 52 has a first end connected to the second end of the series IDT electrode 51 and a second end. The series IDT electrode 53 has a first end connected to the second end of the series IDT electrode 52 and a second end. The series IDT electrode 54 has a first end connected to the second end of the series IDT electrode 53 and a second end connected to the third terminal T3.

The parallel lines P61 to P63 are each a transmission line through which radio frequency signals travel, for example, and branch off from the series line S50. In the present preferred embodiment, the parallel line P61 branches off from a node N61 located between the series IDT electrode 51 and the series IDT electrode 52 on the series line S50. The parallel line P62 branches off from a node N62 located between the series IDT electrode 52 and the series IDT electrode 53 on the series line S50. The parallel line P63 branches off from a node N63 located between the series IDT electrode 53 and the series IDT electrode 54 on the series line S50.

The parallel IDT electrodes 61 to 63 are provided on the respective parallel lines P61 to P63. In the present preferred embodiment, the parallel IDT electrode 61 has a first end connected to the node N61 and a grounded second end. The parallel IDT electrode 62 has a first end connected to the node N62 and a grounded second end. The parallel IDT electrode 63 has a first end connected to the node N63 and a grounded second end.

In the filter device 17, the series IDT electrode 32 is the first-type electrode 151. At least one of the series IDT electrodes 31 to 34 except the first-type electrode 151, the parallel IDT electrodes 41 to 43, the series IDT electrodes 51 to 54, and the parallel IDT electrodes 61 to 63 is the second-type electrode 152. The remaining of the series IDT electrodes 31 to 34, the parallel IDT electrodes 41 to 43, the series IDT electrodes 51 to 54, and the parallel IDT electrodes 61 to 63 are each the first-type electrode 151 or the second-type electrode 152.

In the present preferred embodiment, the series IDT electrodes 31, 33, and 34, the parallel IDT electrodes 41 to 43, the series IDT electrodes 51 to 54, and the parallel IDT electrodes 61 to 63 are each the second-type electrode 152.

Note that although the configuration in which the series IDT electrode 32 is the first-type electrode 151 has been described, the present invention is not limited to this. A configuration in which any of the series IDT electrodes 31, 33, and 34 is the first-type electrode 151 instead of the series IDT electrode 32 may be used. Further, a configuration in which two or more of the series IDT electrodes 31 to 34 are each the first-type electrode 151 may be used.

Further, although, with the filter device 17, the configuration in which the four series IDT electrodes are provided on the series line S50 has been described, the present invention is not limited to this. A configuration in which three or less or five or more series IDT electrodes are provided on the series line S50 may be used.

Further, although, with the filter device 17, the configuration in which the three parallel lines each branch off from the series line S50 has been described, the present invention is not limited to this. The filter device 17 may have a configuration in which two or less or four or more parallel lines each branch off from the series line S50. In this case, one or more parallel IDT electrodes are provided on each parallel line.

### Eighth Preferred Embodiment

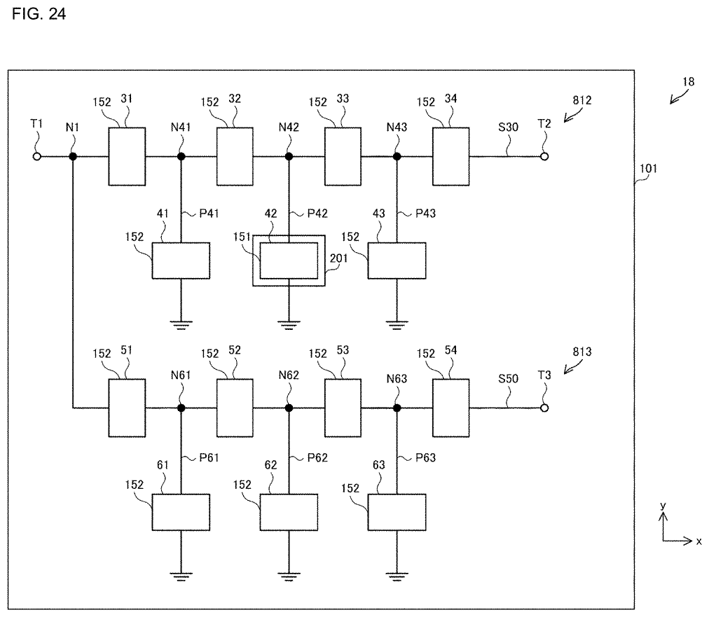

A filter device according to an eighth preferred embodiment is described. FIG. 24 is a diagram illustrating the circuit configuration of a filter device 18. As illustrated in FIG. 24, the filter device 18 according to the eighth preferred embodiment is different from the filter device 17 according to the seventh preferred embodiment in that the first-type electrode 151 is provided on the parallel line.

In the filter device 18, as compared to the filter device 17 illustrated in FIG. 23, the dielectric layer 201 is provided between the parallel IDT electrode 42 and the substrate 101 while the dielectric layer 201 is not provided between the series IDT electrode 32 and the substrate 101.

The filter device 18 includes two ladder filters having the first terminal T1 as a common terminal. In the following, the ladder filter between the first terminal T1 and the second terminal T2 in the filter device 18 is sometimes referred to as “filter 812”. The ladder filter between the first terminal T1 and the third terminal T3 in the filter device 18 is sometimes referred to as “filter 813”.

In the present preferred embodiment, the filters 812 and 813 function as band elimination filters, for example. Note that the filters 812 and 813 may function as other filters such as band pass filters.

In the filter device 18, the parallel IDT electrode 42 is the first-type electrode 151. At least one of the parallel IDT electrodes 41 and 43 except the first-type electrode 151, the series IDT electrodes 31 to 34, the series IDT electrodes 51 to 54, and the parallel IDT electrodes 61 to 63 is the second-type electrode 152. The remaining of the parallel IDT electrodes 41 and 43, the series IDT electrodes 31 to 34, the series IDT electrodes 51 to 54, and the parallel IDT electrodes 61 to 63 are each the first-type electrode 151 or the second-type electrode 152.

In the present preferred embodiment, the parallel IDT electrodes 41 and 43, the series IDT electrodes 31 to 34, the series IDT electrodes 51 to 54, and the parallel IDT electrodes 61 to 63 are each the second-type electrode 152.

Note that although the configuration in which the parallel IDT electrode 42 is the first-type electrode 151 has been described, the present invention is not limited to this. A configuration in which any of the parallel IDT electrodes 41 and 43 is the first-type electrode 151 instead of the parallel IDT electrode 42 may be used. Further, a configuration in which two or more of the parallel IDT electrodes 41 to 43 are each the first-type electrode 151 may be used.

Further, the filter device 18 may have a configuration in which the dielectric layer 201 is further provided between the substrate 101 and each of the series IDT electrodes 31 to 34 and the parallel IDT electrodes 41 and 43 and the series IDT electrodes 31 to 34 and the parallel IDT electrodes 41 to 43 are each the first-type electrode 151.

Now, the filter characteristics of the filters 812 and 813 of the filter device 18 in which the series IDT electrodes 31 to 34 and the parallel IDT electrodes 41 to 43 are each the first-type electrode 151 are described.

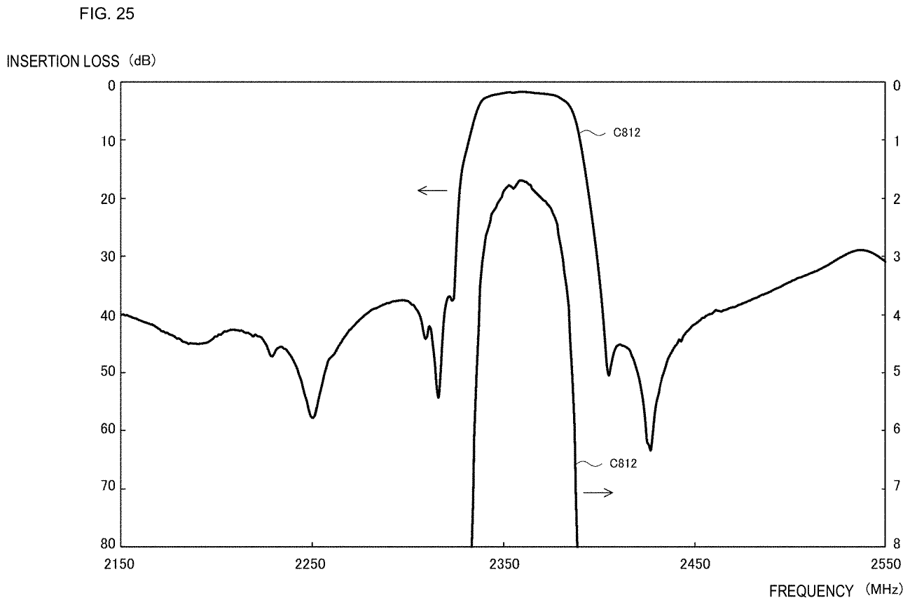

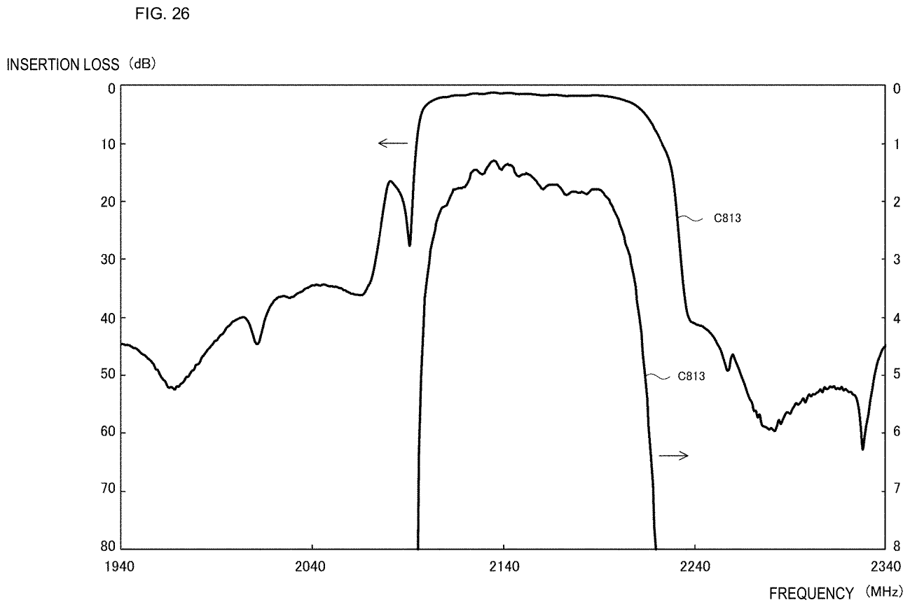

FIG. 25 is a diagram illustrating exemplary frequency characteristics of the filter 812. FIG. 26 is a diagram illustrating exemplary frequency characteristics of the filter 813. Note that FIG. 25 and FIG. 26 can be read in a similar manner to FIG. 8.

As illustrated in FIG. 25, a curve C812 indicates a frequency-dependent change in insertion loss of the filter 812. As illustrated in FIG. 26, a curve C813 indicates a frequency-dependent change in insertion loss of the filter 813.

As illustrated in FIG. 25 and FIG. 26, the filters 812 and 813 each function as a band pass filter. The radio frequency signal pass band of the filter 812 is narrower than the radio frequency signal pass band of the filter 813.

The filter 812 includes the first-type electrode 151, with which the steepness at the end portion of the band of the filter can be easily ensured, so that the filter 812 can be easily configured as a narrow band pass filter. Further, a wide band pass filter that permits a small degree of steepness at the end portion of the band of the filter can be easily realized by the filter 813 including the second-type electrode 152.

That is, with the first-type electrode 151 and the second-type electrode 152 formed on the same substrate 101, the wide band filter and the narrow band filter that have favorable characteristics can be realized on the single substrate 101. With this, as compared to a case where the narrow band filter 812 and the wide band filter 813 are formed on separate substrates, the filters 812 and 813 can be arranged in an aggregated manner so that the space for arranging the filters 812 and 813 can be reduced to reduce the circuit scale.

Note that although, with the filter device 13 (see FIG. 15), the configuration in which the series IDT electrode 32S is connected in series to the series IDT electrode 32 having the largest pitch has been described, the present invention is not limited to this. For example, a configuration in which two or more of the series IDT electrodes 31 to 34 are each the first-type electrode 151 and the series IDT electrode 32S is connected in series to the first-type electrode 151 of the two or more first-type electrodes 151 in question that has the pitch P1 that is not largest may be used.

Further, although, with the filter device 15 (see FIG. 19), the configuration in which the series IDT electrode 32P is connected in parallel to the series IDT electrode 32 having the largest pitch has been described, the present invention is not limited to this. For example, a configuration in which two or more of the series IDT electrodes 31 to 34 are each the first-type electrode 151 and the series IDT electrode 32P is connected in parallel to the first-type electrode 151 of the two or more first-type electrodes 151 in question that has the pitch P1 that is not largest may be used.

Further, although, with the filter device 14 (see FIG. 18), the configuration in which the parallel IDT electrode 42S is connected in series to the parallel IDT electrode 42 having the smallest pitch has been described, the present invention is not limited to this. For example, a configuration in which two or more of the parallel IDT electrodes 41 to 44 are each the first-type electrode 151 and the parallel IDT electrode 42S is connected in series to the first-type electrode 151 of the two or more first-type electrodes 151 in question that has the pitch P1 that is not smallest may be used.

Further, although, with the filter device 16 (see FIG. 22), the configuration in which the parallel IDT electrode 42P is connected in parallel to the parallel IDT electrode 42 having the smallest pitch has been described, the present invention is not limited to this. For example, a configuration in which two or more of the parallel IDT electrodes 41 to 44 are each the first-type electrode 151 and the parallel IDT electrode 42P is connected in parallel to the first-type electrode 151 of the two or more first-type electrodes 151 in question that has the pitch P1 that is not smallest may be used.

The illustrative preferred embodiments of the present invention have been described above. The filter devices 11, 13, and 15 each may include the series line S30 that connects the first terminal T1 and the second terminal T2 to each other, the one or more first parallel lines (parallel lines P41 to P43) that branch off from the series line S30; the two or more first series IDT electrodes (series IDT electrodes 31 to 34) provided on the series line S30, the one or more first parallel IDT electrodes (parallel IDT electrodes 41 to 43) provided on the one or more first parallel lines, the substrate 101 that is piezoelectric, and the dielectric layer 201 provided on a portion of the substrate 101. At least one of the two or more first series IDT electrodes is the first-type electrode 151. The dielectric layer 201 is provided between the first-type electrode 151 and the substrate 101. At least one of the two or more first series IDT electrodes except the first-type electrode 151 and the one or more first parallel IDT electrodes is the second-type electrode 152 directly formed on the substrate 101. The two or more first series IDT electrodes and the one or more first parallel IDT electrodes each have the electrode fingers 72a and 72b formed at the pitch P1 based on a resonant frequency. Then, a first series IDT electrode of the two or more first series IDT electrodes that has the electrode fingers 72a and 72b at the pitch P1 that is largest is the first-type electrode 151.

With such a configuration, a first-type resonator including the first-type electrode 151, the dielectric layer 201, and the substrate 101 and having a small coupling coefficient and a second-type resonator including the second-type electrode 152 and the substrate 101 and having a large coupling coefficient can be connected to each other on the single substrate 101. With this, filter characteristics having a small resonant frequency difference (steep filter characteristics) provided by the first-type resonator and filter characteristics having a large resonant frequency difference (gentle filter characteristics) provided by the second-type resonator can be realized on the single substrate 101. Then, while a wide filter band can be achieved by the second-type resonator, the steepness at the end portion of the band in question can be ensured by the first-type resonator. Thus, a filter device that has a wide pass band or stop band and ensures the steepness near the pass band and the stop band can be provided. Further, as compared to a case where a first-type resonator and a second-type resonator are formed on separate substrates, the resonators can be arranged in an aggregated manner so that the size of the filter device can be reduced.

Further, the filter devices 12, 14, and 16 each may include the series line S30 that connects the first terminal T1 and the second terminal T2 to each other, the two or more first parallel lines (parallel lines P41 to P44) that branch off from the series line S30, the one or more first series IDT electrodes (series IDT electrodes 31 to 35) provided on the series line S30, the two or more first parallel IDT electrodes (parallel IDT electrodes 41 to 44) each provided on a corresponding one of the two or more first parallel lines; the substrate 101 that is piezoelectric, and the dielectric layer 201 provided on a portion of the substrate 101. At least one of the two or more first parallel IDT electrodes is the first-type electrode 151. The dielectric layer 201 is provided between the first-type electrode 151 and the substrate 101. At least one of the two or more first parallel IDT electrodes except the first-type electrode 151 and the one or more first series IDT electrodes is the second-type electrode 152 directly formed on the substrate 101. The one or more first series IDT electrodes and the two or more first parallel IDT electrodes each have the electrode fingers 72a and 72b formed at the pitch P1 based on a resonant frequency. Then, a first parallel IDT electrode of the two or more first parallel IDT electrodes that has the electrode fingers 72a and 72b at the pitch P1 that is smallest is the first-type electrode 151.

With such a configuration, a first-type resonator including the first-type electrode 151, the dielectric layer 201, and the substrate 101 and having a small coupling coefficient and a second-type resonator including the second-type electrode 152 and the substrate 101 and having a large coupling coefficient can be connected to each other on the single substrate 101. With this, filter characteristics having a small resonant frequency difference (steep filter characteristics) provided by the first-type resonator and filter characteristics having a large resonant frequency difference (gentle filter characteristics) provided by the second-type resonator can be realized on the single substrate 101. Then, while a wide filter band can be achieved by the second-type resonator, the steepness at the end portion of the band in question can be ensured by the first-type resonator. Thus, a filter device that has a wide pass band or stop band and ensures the steepness near the pass band and the stop band can be provided. Further, as compared to a case where a first-type resonator and a second-type resonator are formed on separate substrates, the resonators can be arranged in an aggregated manner so that the size of the filter device can be reduced.

Further, the filter device 17 may includes the series line S30 that connects the first terminal T1 and the second terminal T2 to each other, the one or more first parallel lines (parallel lines P41 to P43) that branch off from the series line S30, the series line S50 that connects the first terminal T1 and the third terminal T3 to each other, the one or more second parallel lines (parallel lines P61 to P63) that branch off from the series line S50, the two or more first series IDT electrodes (series IDT electrodes 31 to 34) provided on the series line S30, the one or more first parallel IDT electrodes (parallel IDT electrodes 41 to 43) provided on the one or more first parallel lines, the one or more second series IDT electrodes (series IDT electrodes 51 to 54) provided on the series line S50, the one or more second parallel IDT electrodes (parallel IDT electrodes 61 to 63) provided on the one or more second parallel lines, the substrate 101 that is piezoelectric, and the dielectric layer 201 provided on a portion of the substrate 101. At least one of the two or more first series IDT electrodes is the first-type electrode 151. The dielectric layer 201 is provided between the first-type electrode 151 and the substrate 101. At least one of the two or more first series IDT electrodes except the first-type electrode 151, the one or more first parallel IDT electrodes, the one or more second series IDT electrodes, and the one or more second parallel IDT electrodes is the second-type electrode 152 directly formed on the substrate 101. The two or more first series IDT electrodes, the one or more first parallel IDT electrodes, the one or more second series IDT electrodes, and the one or more second parallel IDT electrodes each have the electrode fingers 72a and 72b formed at the pitch P1 based on a resonant frequency. Then, a first series IDT electrode of the two or more first series IDT electrodes that has the electrode fingers 72a and 72b at the pitch P1 that is largest is the first-type electrode 151.

With such a configuration, a first-type resonator including the first-type electrode 151, the dielectric layer 201, and the substrate 101 and having a small coupling coefficient and a second-type resonator including the second-type electrode 152 and the substrate 101 and having a large coupling coefficient can be connected to each other on the single substrate 101. With this, filter characteristics having a small resonant frequency difference (steep filter characteristics) provided by the first-type resonator and filter characteristics having a large resonant frequency difference (gentle filter characteristics) provided by the second-type resonator can be realized on the single substrate 101. Then, while a wide filter band can be achieved by the second-type resonator, the steepness at the end portion of the band in question can be ensured by the first-type resonator. Thus, a filter device that has a wide pass band or stop band and ensures the steepness near the pass band and the stop band can be provided. Further, as compared to a case where a first-type resonator and a second-type resonator are formed on separate substrates, the resonators can be arranged in an aggregated manner so that the size of the filter device can be reduced. Further, two filters can be realized on the single substrate 101.

Further, the filter device 18 may includes the series line S30 that connects the first terminal T1 and the second terminal T2 to each other, the two or more first parallel lines (parallel lines P41 to P43) that branch off from the series line S30, the series line S50 that connects the first terminal T1 and the third terminal T3 to each other; the one or more second parallel lines (parallel lines P61 to P63) that branch off from the series line S50, the one or more first series IDT electrodes (series IDT electrodes 31 to 34) provided on the series line S30, the two or more first parallel IDT electrodes (parallel IDT electrodes 41 to 43) each provided on a corresponding one of the two or more first parallel lines, the one or more second series IDT electrodes (series IDT electrodes 51 to 54) provided on the series line S50, the one or more second parallel IDT electrodes (parallel IDT electrodes 61 to 63) provided on the second parallel lines, the substrate 101 that is piezoelectric, and the dielectric layer 201 provided on a portion of the substrate 101. At least one of the two or more first parallel IDT electrodes is the first-type electrode 151. The dielectric layer 201 is provided between the first-type electrode 151 and the substrate 101. At least one of the two or more first parallel IDT electrodes except the first-type electrode 151, the one or more first series IDT electrodes, the one or more second series IDT electrodes, and the one or more second parallel IDT electrodes is the second-type electrode 152 directly formed on the substrate 101. The one or more first series IDT electrodes, the two or more first parallel IDT electrodes, the one or more second series IDT electrodes, and the one or more second parallel IDT electrodes each have the electrode fingers 72a and 72b formed at the pitch P1 based on a resonant frequency. Then, a first parallel IDT electrode of the two or more first parallel IDT electrodes that has the electrode fingers 72a and 72b at the pitch P1 that is smallest is the first-type electrode 151.

With such a configuration, a first-type resonator including the first-type electrode 151, the dielectric layer 201, and the substrate 101 and having a small coupling coefficient and a second-type resonator including the second-type electrode 152 and the substrate 101 and having a large coupling coefficient can be connected to each other on the single substrate 101. With this, filter characteristics having a small resonant frequency difference (steep filter characteristics) provided by the first-type resonator and filter characteristics having a large resonant frequency difference (gentle filter characteristics) provided by the second-type resonator can be realized on the single substrate 101. Then, while a wide filter band can be achieved by the second-type resonator, the steepness at the end portion of the band in question can be ensured by the first-type resonator. Thus, a filter device that has a wide pass band or stop band and ensures the steepness near the pass band and the stop band can be provided. Further, as compared to a case where a first-type resonator and a second-type resonator are formed on separate substrates, the resonators can be arranged in an aggregated manner so that the size of the filter device can be reduced. Further, two filters can be realized on the single substrate 101.

Further, in the filter device 13, the two or more first series IDT electrodes include the series connection electrode (series IDT electrode 32S) that is one of the first series IDT electrodes connected in series to the first-type electrode 151 (series IDT electrode 32), which is provided on the series line S30, without the interposition of a node at which the first parallel line branches off.

With such a configuration, while a wide filter band can be achieved, a steep frequency-dependent change in filter characteristics can be made at a desired frequency. Further, the electric power handling capability at the end portion of the band of the filter can be improved.

Further, in the filter device 14, the two or more first parallel IDT electrodes include the series connection electrode (parallel IDT electrode 42S) that is one of the first parallel IDT electrodes connected in series to the first-type electrode 151 (parallel IDT electrode 42) provided on one of the first parallel lines.

With such a configuration, while a wide filter band can be achieved, a steep frequency-dependent change in filter characteristics can be made at a desired frequency. Further, the electric power handling capability at the end portion of the band of the filter can be improved.

Further, in the filter devices 13 and 14, the series connection electrode is the second-type electrode 152.

In this way, with the configuration in which the first-type electrode 151 and the second-type electrode 152 are connected in series to each other, filter characteristics based on the configuration in question can be realized.

Further, in the filter devices 13 and 14, in the plan view of the substrate 101, the size of the first-type electrode 151 connected in series to the series connection electrode is larger than the size of the series connection electrode in question.

Although the dielectric layer 201 is provided and the electrical coupling between the first-type electrode 151 and the substrate 101 thus drops, with the configuration in which the size of the first-type electrode 151 is larger than the size of the series connection electrode in question, the coupling in question can be increased by virtue of the size of the first-type electrode 151. With this, the first-type electrode 151, the dielectric layer 201, and the substrate 101 can appropriately function as a resonator. Further, with the first-type electrode 151 being large in size, the electric power handling capability of the first-type electrode 151 can be improved.

Further, in the filter devices 13 and 14, the series connection electrode is the first-type electrode 151.

In this way, with the configuration in which the first-type electrodes 151 are connected in series to each other, filter characteristics based on the configuration in question can be realized.

Further, in the filter device 15, the two or more first series IDT electrodes include the parallel connection electrode (series IDT electrode 32P) that is one of the first series IDT electrodes connected in parallel to the first-type electrode 151 (series IDT electrode 32) provided on the series line S30.

With such a configuration, while a wide filter band can be achieved, a steep frequency-dependent change in filter characteristics can be made at a desired frequency. Further, the electric power handling capability at the end portion of the band of the filter can be improved.

Further, in the filter device 16, the two or more first parallel IDT electrodes include the parallel connection electrode (parallel IDT electrode 42P) that is one of the first parallel IDT electrodes connected in parallel to the first-type electrode 151 (parallel IDT electrode 42), which is provided on the parallel line P42, without the interposition of the first series IDT electrode.

With such a configuration, while a wide filter band can be achieved, a steep frequency-dependent change in filter characteristics can be made at a desired frequency. Further, the electric power handling capability at the end portion of the band of the filter can be improved.

Further, in the filter devices 15 and 16, the parallel connection electrode is the second-type electrode 152.

In this way, with the configuration in which the first-type electrode 151 and the second-type electrode 152 are connected in parallel to each other, filter characteristics based on the configuration in question can be realized.

Further, in the filter devices 15 and 16, in the plan view of the substrate 101, the size of the first-type electrode 151 connected in parallel to the parallel connection electrode is larger than the size of the parallel connection electrode.

Although provision to the dielectric layer 201 is made and the electrical coupling between the first-type electrode 151 and the substrate 101 thus drops, with the configuration in which the size of the first-type electrode 151 is larger than the size of the parallel connection electrode in question, the coupling in question can be increased by virtue of the size of the first-type electrode 151. With this, the first-type electrode 151, the dielectric layer 201, and the substrate 101 can appropriately function as a resonator. Further, with the first-type electrode 151 being large in size, the electric power handling capability of the first-type electrode 151 can be improved.

Further, in the filter devices 15 and 16, the parallel connection electrode is the first-type electrode 151.

In this way, with the configuration in which the first-type electrodes 151 are connected in parallel to each other, filter characteristics based on the configuration in question can be realized.

Further, in the filter devices 11 to 19, when a radio frequency signal is transmitted through the series line S30, a frequency component included in a predetermined frequency band of the radio frequency signal in question is attenuated.

With such a configuration, the filter devices 11 to 19 can each function as a band elimination filter to prevent radio frequency signals included in the predetermined frequency band in question from being transmitted to the subsequent circuits.

Further, in the filter devices 17 and 18, the series IDT electrodes 51 to 54 and the parallel IDT electrodes 61 to 63 are each the second-type electrode 152.

With such a configuration, a wide band filter that permits a small degree of steepness of a frequency-dependent change in filter characteristics at the end portion of the band can be easily realized by each of the filters 713 and 813 each including the second-type electrode 152 between the first terminal T1 and the third terminal T3.

Further, in the filter device 18, the series IDT electrodes 31 to 34 and the parallel IDT electrodes 41 to 43 are each the first-type electrode 151.

In this way, the filter 812 between the first terminal T1 and the second terminal T2 includes the first-type electrode 151, with which the degree of steepness of a frequency-dependent change in filter characteristics at the end portion of the band of the filter can be easily increased, so that the filter 812 can be easily configured as a narrow band filter. Further, as compared to a case where a narrow band filter and a wide band filter are formed on separate substrates, the narrow band filter 812 and the wide band filter 813 can be arranged in an aggregated manner so that the space for arranging the filters 812 and 813 can be reduced to reduce the circuit scale.

Further, in the filter devices 11 to 18, the temperature coefficient of frequency of the first-type electrode 151 is smaller than the temperature coefficient of frequency of the second-type electrode 152.

With such a configuration, the filter device can favorably function as a filter over a wide environmental temperature range and the electric power handling capability at the end portion of the band of the filter can be improved.

Note that the preferred embodiments described above are intended to facilitate the understanding of the present invention and are not to be interpreted as limiting the present invention. The present invention may be modified or improved without departing from the gist thereof and equivalents to the present invention are also included in the present invention. In other words, appropriate design changes made to the preferred embodiments by those skilled in the art are also included in the scope of the present invention. For example, the elements included in the preferred embodiments and the arrangements, materials, conditions, shapes, sizes, and the like of the elements are not limited to those exemplified in the preferred embodiments and can be appropriately changed. Further, the preferred embodiments are illustrative and the components described in the different preferred embodiments may be partially replaced or combined, and they are also included in the scope of the present invention.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
a first series line that connects a first terminal and a second terminal to each other;
one or more first parallel lines extending from the first series line;
two or more first series IDT electrodes on the first series line;
one or more first parallel IDT electrodes on the one or more first parallel lines;
a substrate that is piezoelectric; and
a dielectric layer on a portion of the substrate; wherein
at least one of the two or more first series IDT electrodes is a first-type electrode;
the dielectric layer is between the first-type electrode and the substrate;
at least one of the two or more first series IDT electrodes except the first-type electrode or at least one of the one or more first parallel IDT electrodes or any combination thereof is a second-type electrode directly contacting the substrate;
the two or more first series IDT electrodes and the one or more first parallel IDT electrodes each include electrode fingers positioned at a pitch based on a resonant frequency; and
a first series IDT electrode of the two or more first series IDT electrodes that has the electrode fingers at the pitch that is largest is the first-type electrode.

2. A filter device comprising:
a first series line that connects a first terminal and a second terminal to each other;
two or more first parallel lines extending from the first series line;
one or more first series IDT electrodes on the first series line;
two or more first parallel IDT electrodes each on a corresponding one of the two or more first parallel lines;
a substrate that is piezoelectric; and
a dielectric layer on a portion of the substrate; wherein
at least one of the two or more first parallel IDT electrodes is a first-type electrode;
the dielectric layer is between the first-type electrode and the substrate;
at least one of the two or more first parallel IDT electrodes except the first-type electrode or at least one of the one or more first series IDT electrodes or any combination thereof is a second-type electrode directly contacting the substrate;
the one or more first series IDT electrodes and the two or more first parallel IDT electrodes each include electrode fingers positioned at a pitch based on a resonant frequency; and
a first parallel IDT electrode of the two or more first parallel IDT electrodes that has the electrode fingers at the pitch that is smallest is the first-type electrode.

3. A filter device comprising:
a first series line that connects a first terminal and a second terminal to each other;
one or more first parallel lines extending from the first series line;
a second series line that connects the first terminal and a third terminal to each other;
one or more second parallel lines that branch extending from the second series line;
two or more first series IDT electrodes on the first series line;
one or more first parallel IDT electrodes on the one or more first parallel lines;
one or more second series IDT electrodes on the second series line;
one or more second parallel IDT electrodes on the one or more second parallel lines;
a substrate that is piezoelectric; and
a dielectric layer on a portion of the substrate; wherein
at least one of the two or more first series IDT electrodes is a first-type electrode;
the dielectric layer is between the first-type electrode and the substrate;
at least one of the two or more first series IDT electrodes except the first-type electrode, at least one of the one or more first parallel IDT electrodes, at least one of the one or more second series IDT electrodes, or at least one of the one or more second parallel IDT electrodes or any combination thereof is a second-type electrode directly contacting the substrate;
the two or more first series IDT electrodes, the one or more first parallel IDT electrodes, the one or more second series IDT electrodes, and the one or more second parallel IDT electrodes each include electrode fingers positioned at a pitch based on a resonant frequency; and
a first series IDT electrode of the two or more first series IDT electrodes that has the electrode fingers at the pitch that is largest is the first-type electrode.

4. A filter device comprising:
a first series line that connects a first terminal and a second terminal to each other;
two or more first parallel lines extending from the first series line;
a second series line that connects the first terminal and a third terminal to each other;
one or more second parallel lines extending from the second series line;
one or more first series IDT electrodes on the first series line;
two or more first parallel IDT electrodes each on a corresponding one of the two or more first parallel lines;
one or more second series IDT electrodes on the second series line;
one or more second parallel IDT electrodes on the second parallel lines;
a substrate that is piezoelectric; and
a dielectric layer on a portion of the substrate; wherein
at least one of the two or more first parallel IDT electrodes is a first-type electrode;
the dielectric layer is between the first-type electrode and the substrate;
at least one of the two or more first parallel IDT electrodes except the first-type electrode, at least one of the one or more first series IDT electrodes, at least one of the one or more second series IDT electrodes, or at least one of the one or more second parallel IDT electrodes or any combination thereof is a second-type electrode directly contacting with the substrate;
the one or more first series IDT electrodes, the two or more first parallel IDT electrodes, the one or more second series IDT electrodes, and the one or more second parallel IDT electrodes each include electrode fingers positioned at a pitch based on a resonant frequency; and
a first parallel IDT electrode of the two or more first parallel IDT electrodes that has the electrode fingers at the pitch that is smallest is the first-type electrode.

5. The filter device according to claim 1, wherein the two or more first series IDT electrodes include a series connection electrode that is one of the first series IDT electrodes connected in series to the first-type electrode, which is on the first series line, without interposition of a node from which the first parallel line extends.

6. The filter device according to claim 2, wherein the two or more first series IDT electrodes include a series connection electrode that is one of the first series IDT electrodes connected in series to the first-type electrode, which is on the first series line, without interposition of a node from which the first parallel line extends.

7. The filter device according to claim 3, wherein the two or more first series IDT electrodes include a series connection electrode that is one of the first series IDT electrodes connected in series to the first-type electrode, which is on the first series line, without interposition of a node from which the first parallel line extends.

8. The filter device according to claim 2, wherein the two or more first parallel IDT electrodes include a series connection electrode that is one of the first parallel IDT electrodes connected in series to the first-type electrode on one of the first parallel lines.

9. The filter device according to claim 5, wherein the series connection electrode is the second-type electrode.

10. The filter device according to claim 9, wherein in a plan view of the substrate, a size of the first-type electrode connected in series to the series connection electrode is larger than a size of the series connection electrode.

11. The filter device according to claim 5, wherein the series connection electrode is the first-type electrode.

12. The filter device according to claim 1, wherein the two or more first series IDT electrodes include a parallel connection electrode that is one of the first series IDT electrodes connected in parallel to the first-type electrode on the first series line.

13. The filter device according to claim 2, wherein the two or more first parallel IDT electrodes include a parallel connection electrode that is one of the first parallel IDT electrodes connected in parallel to the first-type electrode, which is on one of the first parallel lines, without interposition of the first series IDT electrode.

14. The filter device according to claim 12, wherein the parallel connection electrode is the second-type electrode.

15. The filter device according to claim 14, wherein in a plan view of the substrate, a size of the first-type electrode connected in parallel to the parallel connection electrode is larger than a size of the parallel connection electrode.

16. The filter device according to claim 12, wherein the parallel connection electrode is the first-type electrode.

17. The filter device according to claim 1, wherein when a radio frequency signal is transmitted through the first series line, a frequency component included in a predetermined frequency band of the radio frequency signal is attenuated.

18. The filter device according to claim 3, wherein the second series IDT electrode and the second parallel IDT electrode are each the second-type electrode.

19. The filter device according to claim 3, wherein the first series IDT electrodes and the first parallel IDT electrodes are each the first-type electrode.

20. The filter device according to claim 1, wherein a temperature coefficient of frequency of the first-type electrode is smaller than a temperature coefficient of frequency of the second-type electrode.
